(19) United States
(12) Patent Application Publication
(10) Pub. No.: US 2025/0234554 A1
(43) Pub. Date: Jul. 17, 2025

(54) SEMICONDUCTOR DEVICES

(71) Applicant: Samsung Electronics Co., Ltd., Suwon-si (KR)

(72) Inventors: Yunjo Lee, Suwon-si (KR); Kangoh Yun, Suwon-si (KR); Dongjin Lee, Suwon-si (KR); Jaeduk Lee, Suwon-si (KR)

(21) Appl. No.: 18/883,072

(22) Filed: Sep. 12, 2024

(30) Foreign Application Priority Data
Jan. 12, 2024 (KR) 10-2024-0005449

(51) Int. Cl. H10B 43/40; H01L 23/00; H01L 25/00; H01L 25/065; H01L 25/18; H10B 41/27; H10B 41/41; H10B 43/27; H10B 80/00

(52) U.S. Cl. CPC H10B 43/40; H01L 24/08; H01L 24/80; H01L 25/0657; H01L 25/18; H01L 25/50; H10B 41/27; H10B 41/41; H10B 43/27; H10B 80/00; H01L 2224/08145; H01L 2224/80895; H01L 2224/80896; H01L 2225/06541; H01L 2924/1431; H01L 2924/14511

(57) ABSTRACT

A semiconductor device includes a first peripheral circuit structure, a second peripheral circuit structure, a first through-via, and a cell structure. The first peripheral structure includes a first substrate that includes a first page buffer region, a first peripheral circuit having a first gate stack having a first height, and first peripheral interconnections. The second peripheral circuit structure includes a second substrate that includes a second page buffer region, a second peripheral circuit having a second gate stack having a second height greater than the first height, second peripheral interconnections. The cell structure includes gate electrodes, channel structures that extend into the gate electrodes, and cell interconnections electrically connected to the gate electrodes and the channel structures.

### CROSS-REFERENCE TO RELATED APPLICATION(S)

This application claims benefit of priority to Korean Patent Application No. 10-2024-0005449 filed on Jan. 12, 2024 in the Korean Intellectual Property Office, the disclosure of which is incorporated herein by reference in its entirety.

### BACKGROUND

Example embodiments of the present disclosure relate to a semiconductor device.

A semiconductor device may include a cell structure in which memory cells to which data is written are disposed, and peripheral circuit structures in which a circuit for controlling the cell structure is disposed. The peripheral circuit structure may include a page buffer, a row decoder, a control logic circuit, a voltage generator, and the like, and the row decoder may be connected to the cell region through word lines, ground select lines, and string select lines.

Recently, with the multifunctionalization of information technology (IT) devices, there has been a demand for higher capacity and higher integration of a memory device. To increase capacity and integration of a memory device, the cell structure and the peripheral circuit structure of a semiconductor device may be formed in a chip to chip (C2C) structure.

### SUMMARY

Example embodiments of the present disclosure is to provide a semiconductor device having improved electrical properties and integration density.

According to example embodiments of the present disclosure, a semiconductor device includes a first peripheral circuit structure including: a first substrate that includes a first page buffer region, a first peripheral circuit that is on the first page buffer region and includes a first gate stack that extends from the first substrate by a first height in a first direction that is perpendicular to a first surface of the first substrate, and first peripheral interconnections electrically connected to the first peripheral circuit. The semiconductor device includes a second peripheral circuit structure on the first peripheral circuit structure, where the second peripheral circuit structure includes: a second substrate including a second page buffer region that at least partially overlaps the first page buffer region in the first direction, a second peripheral circuit that is on the second page buffer region and includes a second gate stack that extends from the second substrate by a second height in the first direction, where the second height is greater than the first height, and second peripheral interconnections electrically connected to the second peripheral circuit; a first through-via that extends into the second substrate and electrically connects the first peripheral interconnections to the second peripheral interconnections. The semiconductor device includes a cell structure on the second peripheral circuit structure, where the cell structure includes: gate electrodes, channel structures that extend into the gate electrodes, and cell interconnections electrically connected to the gate electrodes and the channel structures.

According to example embodiments of the present disclosure, a semiconductor device includes a first peripheral circuit structure including: a first substrate, a first peripheral circuit that includes a first gate stack that is on the first substrate and extends from the first substrate by a first height in a first direction that is perpendicular to a first surface of the first substrate, first peripheral interconnections electrically connected to the first peripheral circuit, and a first interlayer insulating layer that at least partially overlaps the first peripheral circuit and the first peripheral interconnections in the first direction. The semiconductor device includes a second peripheral circuit structure including: a second substrate that contacts the first interlayer insulating layer, a second peripheral circuit that includes a second gate stack that is on the second substrate and extends from the second substrate by a second height in the first direction that is greater than the first height, second peripheral interconnections electrically connected to the second peripheral circuit, and a first bonding pad electrically connected to the second peripheral interconnections. The semiconductor device includes a cell structure including: a second bonding pad on the first bonding pad, gate electrodes, channel structures that extend in the first direction and extend into the gate electrodes, and cell interconnections electrically connected to the gate electrodes and the channel structures.

According to example embodiments of the present disclosure, a semiconductor device includes a substrate including a cell array region, a cell contact region, and a peripheral region; a first peripheral circuit structure on the substrate, where the first peripheral circuit structure includes: a first page buffer that at least partially overlaps the cell array region in a first direction that is perpendicular to an upper surface of the substrate and has a first operating voltage, and a first row decoder that at least partially overlaps the cell contact region in the first direction and has a second operating voltage. The semiconductor device includes a second peripheral circuit structure on the first peripheral circuit structure, where the second peripheral circuit structure includes: a second page buffer that at least partially overlaps the cell array region in the first direction and has a third operating voltage that is greater than the first operating voltage, and a second row decoder that at least partially overlaps the cell contact region in the first direction and has a fourth operating voltage that is greater than the second operating voltage. The semiconductor device includes a cell structure on the second peripheral circuit structure, where the cell structure includes: gate electrodes, channel structures that extend into the gate electrodes and are on the cell array region, and cell contacts that at least partially overlap the cell contact region in the first direction, where the second peripheral circuit structure includes a pass circuit that is between the second page buffer and the second row decoder and is configured to provide a fifth operating voltage that is greater than the first operating voltage and the second operating voltage to the cell contacts.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a block diagram illustrating a semiconductor device according to example embodiments of the present disclosure;

FIG. 1B is a block diagram illustrating a block diagram illustrating a connection relationship between a cell structure and first and second peripheral circuit structures of a semiconductor device according to example embodiments of the present disclosure;

FIG. 1C is an equivalent circuit diagram illustrating a memory cell array in FIG. 1A according to example embodiments of the present disclosure;

FIG. 2 is a perspective diagram illustrating a semiconductor device according to example embodiments of the present disclosure;

FIG. 3A is a circuit diagram illustrating a mat structure of a cell structure in FIG. 2 according to example embodiments of the present disclosure;

FIG. 3B is a plan diagram illustrating a first peripheral circuit structure and a second peripheral circuit structure according to example embodiments of the present disclosure;

FIG. 4 is a cross-sectional diagram illustrating a semiconductor device according to example embodiments of the present disclosure;

FIG. 5A is an enlarged diagram illustrating region A in FIG. 4 according to example embodiments of the present disclosure;

FIG. 5B is an enlarged diagram illustrating region A in FIG. 4 according to example embodiments of the present disclosure;

FIG. 6 is an enlarged diagram illustrating region B in FIG. 4 according to example embodiments of the present disclosure;

FIG. 7 is a cross-sectional diagram illustrating the semiconductor device in FIG. 2 according to example embodiments of the present disclosure;

FIG. 8A is an enlarged diagram illustrating C region in FIG. 7 according to example embodiments of the present disclosure;

FIG. 8B is an enlarged diagram illustrating D region in FIG. 7 according to example embodiments of the present disclosure;

FIG. 9 is a perspective diagram illustrating a semiconductor device according to example embodiments of the present disclosure;

FIG. 10 is a cross-sectional diagram illustrating a semiconductor device according to example embodiments of the present disclosure;

FIGS. 11A, 11B, 11C, 11D, 11E, and 11F are diagrams illustrating a method of manufacturing the semiconductor device in FIG. 4 according to example embodiments of the present disclosure;

FIGS. 12A, 12B, 12C, 12D, 12E, and 12F are diagrams illustrating a method of manufacturing the semiconductor device in FIG. 10 according to example embodiments of the present disclosure;

FIG. 13 is a diagram illustrating a data storage system including a semiconductor device according to example embodiments of the present disclosure;

FIG. 14 is a perspective diagram illustrating a data storage system including a semiconductor device according to example embodiments of the present disclosure; and

FIG. 15 is a cross-sectional diagram illustrating a semiconductor package according to example embodiments of the present disclosure.

### DETAILED DESCRIPTION

To clarify the present disclosure, parts that are not connected with the description will be omitted, and the same elements or equivalents are referred to by the same reference numerals throughout the specification. In the drawings, the thickness of layers, films, panels, regions, etc., are exaggerated for clarity. Further, since sizes and thicknesses of constituent members shown in the accompanying drawings are arbitrarily given for better understanding and ease of description, the present disclosure is not limited to the illustrated sizes and thicknesses.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Hereinafter, embodiments of the present disclosure will be described as follows with reference to the accompanying drawings.

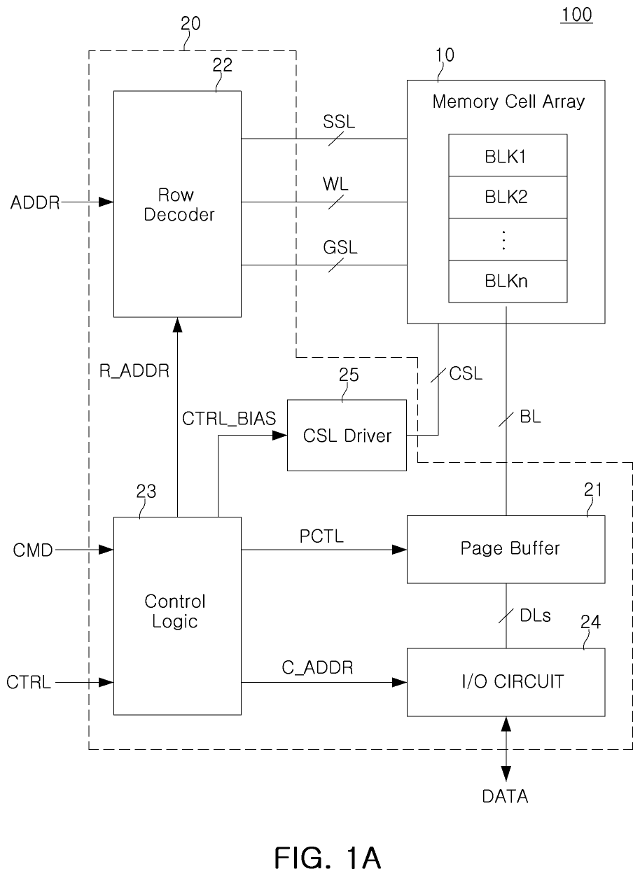

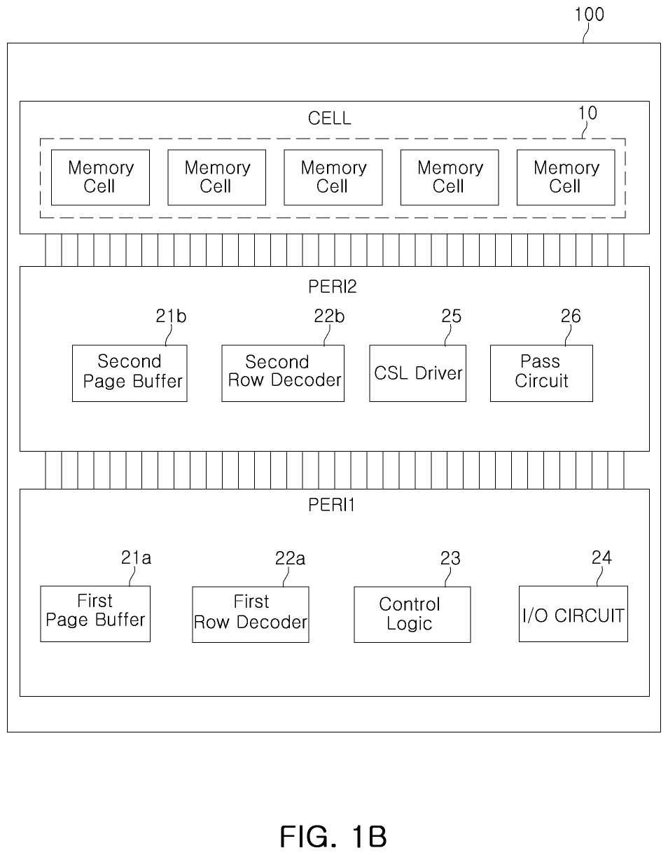

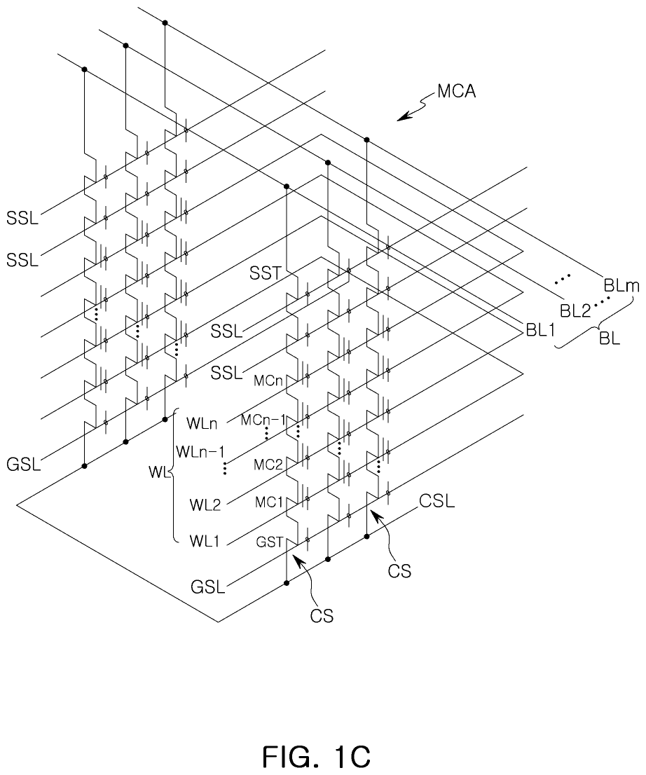

FIG. 1A is a block diagram illustrating a semiconductor device according to example embodiments. FIG. 1B is a block diagram illustrating a block diagram illustrating a connection relationship between a cell structure and first and second peripheral circuit structures of a semiconductor device according to example embodiments.

Referring to FIG. 1A, a semiconductor device 100 may include a memory cell array 10 and a peripheral circuit 20. The memory cell array 10 may include a plurality of memory cell blocks BLK1, BLK2, . . . , BLKn. The plurality of memory cell blocks BLK1, BLK2, . . . , BLKn may be electrically connected to a peripheral circuit 20 through a bit line BL, a word line WL, a string select line SSL, and a ground select line GSL.

The peripheral circuit 20 may include a page buffer 21, a row decoder 22, a control logic 23, an input/output circuit 24, and a common source line driver 25. Although not illustrated in FIG. 1A, the peripheral circuit 20 may further include various circuits such as a voltage generation circuit (or a voltage generator) for generating various voltages for operating/driving the semiconductor device 100, a circuit for storing data read out from the memory cell array 10, and an input/output interface.

The memory cell array 10 may be electrically connected to the page buffer 21 through the bit line BL and may be electrically connected to a row decoder 22 through the word line WL, the string select line SSL, and the ground select line GSL. Each of the plurality of memory cells included in the plurality of memory cells blocks BLK1, BLK2, . . . , BLKn of the memory cell array 10 may be configured as a flash memory cell. The memory cell array 10 may include a three-dimensional memory cell array. The three-dimensional memory cell array may include a plurality of NAND strings, and each of the plurality of NAND strings may include a plurality of memory cells connected to a plurality of word line WL vertically stacked.

The peripheral circuit 20 may receive an address ADDR, a command CMD, and a control signal CTRL from an external entity of the semiconductor device 100, and may transmit data DATA to and receive data DATA from an external device present externally of the semiconductor device 100.

A page buffer 21 may be electrically connected to the memory cell array 10 through the bit line BL. The page buffer 21 may operate as a write driver during a program operation and may apply a voltage according to the data DATA to be stored in the memory cell array 10 to the bit line BL. The page buffer 21 may operate as a sense amplifier during a readout operation and may sense the data DATA stored in the memory cell array 10. The page buffer 21 may operate according to a control signal CTRL provided from a control logic 23.

The row decoder 22 may select at least one of the plurality of cell blocks BLK1, BLK2, . . . , BLKn in response to the address ADDR from an external entity, and may select a word line WL, a string select line SSL, and a ground select line GSL of the selected memory cell block. A row decoder 22 may transfer a voltage for a memory operation of the selected memory cell block performed on the word line WL.

The input/output circuit 24 may be connected to the page buffer 21 through a plurality of data interconnections DLs. The input/output circuit 24 may receive the data DATA from a memory controller (not illustrated) during a program operation and may provide program data DATA to the page buffer 21 based on the column address C_ADDR provided from the control logic 23. The input/output circuit 24 may provide readout data DATA stored in the page buffer 21 to the memory controller based on the column address C_ADDR provided from the control logic 23 during a readout operation.

The input/output circuit 24 may transfer an input address or an input command to the control logic 23 or the row decoder 22. The peripheral circuit 20 may further include an electrostatic discharge (ESD) circuit and a pull-up/pull-down circuit.

The control logic 23 may receive a command CMD and a control signal CTRL from the memory controller. The control logic 23 may provide a row address R_ADDR to the row decoder 22 and may provide a column address C_ADDR to the input/output circuit 24. The control logic 23 may generate various internal control signals used in the semiconductor device 100 in response to the control signal CTRL. For example, the control logic 23 may adjust a voltage level provided by the word line WL and the bit line BL when a memory operation such as a program operation or an erase operation is performed.

The common source line driver 25 may be electrically connected to the memory cell array 10 through the common source line CSL. The common source line driver 25 may apply a common source voltage (e.g., power voltage) or a ground voltage to the common source line CSL based on control of the control logic 23.

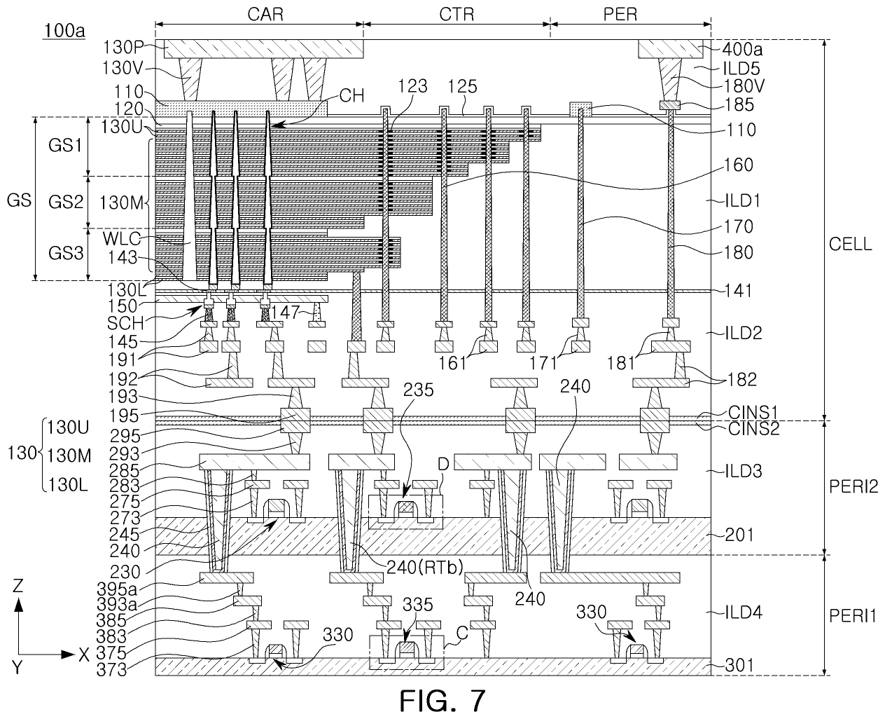

In an example, the peripheral circuit 20 may include a plurality of MOS transistors, and the plurality of MOS transistors may be classified depending on an operating voltage thereof and may be distributed in a plurality of transistor regions. For example, the peripheral circuit 20 may include a first peripheral circuit region (e.g., a first peripheral circuit structure PERI1 in FIG. 1B) in which a plurality of low-voltage MOS transistors are formed and a second peripheral circuit region (e.g., a second peripheral circuit structure PERI2 in FIG. 1B) in which a plurality of high-voltage MOS transistors are formed. Also, the peripheral circuit 20 may include various regions in which MOS transistors having an intermediate voltage, which may have an operating voltage greater than an operating voltage of the low-voltage MOS transistors disposed in the first peripheral circuit region and smaller than an operating voltage of the high-voltage MOS transistors disposed in the second peripheral circuit region, are disposed, which will be described with reference to FIG. 7.

As used herein, “operating voltage” (which may also be interchangeably referred to herein as “driving voltage”) refers to a voltage magnitude that causes a given component of the peripheral circuit 20 to perform an operation on the memory cell array 10 and/or another component of the peripheral circuit 20. As an example, the operating (or driving) voltage may refer to a voltage magnitude between gate and source terminals of at least one MOS transistor of the peripheral circuit 20 that causes the at least one MOS transistor to form a conductive channel between the respective source and drain terminals. As such, the operating (or driving) voltage enables the at least one MOS transistor of the peripheral circuit 20 to perform the functionality described herein. It should be noted that the voltage magnitude between gate and source terminals should not be construed as being limited to a voltage magnitude that causes the MOS transistor to completely turn on. That is, the voltage magnitude between gate source terminals may refer to any voltage magnitude that causes the MOS transistor to at least partially turn on (e.g., voltage magnitudes that cause the MOS transistor to operate in an ohmic or saturation region).

Referring to FIG. 1B, a semiconductor device 100 may include a cell structure CELL, a first peripheral circuit structure PERI1, and a second peripheral circuit structure PERI2.

The cell structure CELL may include a memory cell array 10 as a storage region. The first and second peripheral circuit structures PERI1 and PERI2 may include a peripheral circuit 20 as a peripheral circuit region.

The first peripheral circuit structure PERI1 may include a plurality of low-voltage MOS transistors, and the second peripheral circuit structure PERI2 may include a plurality of high-voltage MOS transistors.

The first peripheral circuit structure PERI1 may include a first page buffer 21a, a first row decoder 22a, a control logic 23, and an input/output circuit 24 having a relatively low operating voltage.

The second peripheral circuit structure PERI2 may include a second page buffer 21b, a second row decoder 22b, a common source line driver 25, and a pass circuit 26 having a relatively high operating voltage.

The page buffer 21 may include a plurality of page buffers 21a and 21b connected to the bit line BL. The plurality of page buffers 21a and 21b may include a second page buffer 21b connected to the bit line BL and a first page buffer 21a connected to the second page buffer 21b.

The first page buffer 21a may be disposed in the first peripheral circuit structure PERI1. The second page buffer 21b may be disposed in the second peripheral circuit structure PERI2. In an example, the first page buffer 21a may have a relatively lower driving voltage, and the second page buffer 21b may have a relatively higher driving voltage.

The pass circuit 26 may control a row line voltage applied to the string select line SSL, the word line WL, and the ground select line GSL. The pass circuit 26 may be disposed in the second peripheral circuit structure PERI2.

The pass circuit 26 may include a plurality of pass transistors. The row line voltage applied to the ground select line GSL, the word line WL, and the ground select line GSL may be controlled based on a switching operation of the plurality of pass transistors.

The row decoder 22 may include drivers for a block selection portion, the string select line SSL, the word line WL, and the ground select line GSL.

The row decoder 22 (e.g., the block selection portion) may select at least one of the plurality of cell blocks BLK1, BLK2, . . . , BLKn in response to the address ADDR from an external entity.

The row decoder 22 (e.g., drivers of the string select line SSL, the word line WL, and the ground select line GSL) may select a word line WL, a string select line SSL, and a ground select line GSL of the selected memory cell block.

The row decoder 22 (e.g., driver of string select line SSL) may be connected to the string select line SSL through the pass circuit 26 and may drive the string select line SSL. For example, the row decoder 22 may float the string select line SSL during an erase operation and may provide a string select voltage (e.g., power voltage) to the string select line SSL during a program operation.

The row decoder 22 (e.g., a driver of the word line WL) may be connected to the word line WL through the pass circuit 26 and may drive the word line WL. For example, during an erase operation, an erase voltage may be applied to a bulk in which the plurality of cell blocks BLK1, BLK2, . . . , BLKn are formed, and a relatively low level word line voltage (e.g., a ground voltage) may be applied to the word line WL. Also, during a program operation, a program voltage may be provided to a selected word line and a pass voltage may be provided to a non-selected word line. The row decoder 22 (e.g., a driver of the ground select line GSL) may drive the ground select line GSL through the pass circuit 26. For example, the row decoder 22 may float the ground select line GSL during an erase operation, and may provide a relatively low level ground select voltage (e.g., a ground voltage) to the ground select line GSL during a program operation.

The row decoder 22 may include a first row decoder 22a having a relatively low level operating voltage and a second row decoder 22b having a relatively high level operating voltage. For example, the first row decoder 22a may provide a low level ground voltage to the word line WL and/or the ground select line GSL, and the second row decoder 22b may provide a high level power voltage to the string select line SSL.

The first row decoder 22a may be disposed in the first peripheral circuit structure PERI1, and the second row decoder 22b may be disposed in the second peripheral circuit structure PERI2.

The control logic 23 may include devices for controlling overall operation of data readout from the memory cell array 10 or data written to the memory cell array 10.

Although not illustrated in FIG. 1B, the first peripheral circuit structure PERI1 may further include a scheduler. The scheduler may perform scheduling for a plurality of operations requested simultaneously for the memory cell array 10. For example, when write and read requests requested simultaneously exceed a threshold reference, the scheduler may control to reduce the number of requests, may delay garbage collection after the plurality of write requests, and may change the order of operations to process the read request. In an example, the scheduler may be included in the control logic 23 or may be disposed as an independent circuit.

Although not illustrated in FIG. 1B, the second peripheral circuit structure PERI2 may further include a charge pump. The charge pump may generate various types of internal voltages to perform program readout and erase operations on the memory cell array 10 based on a control signal received from the control logic 23. In an example, the voltages generated by the charge pump may be transferred to the word line WL, the string select line SSL, or the ground select line GSL of the selected memory cell block through the pass circuit 26 to perform a memory operation.

FIG. 1C is an equivalent circuit diagram illustrating a memory cell array in FIG. 1A according to example embodiments.

FIG. 1C illustrates example embodiments of an equivalent circuit diagram of a vertical NAND flash memory device having a vertical channel structure. Each of the plurality of memory cells blocks BLK1, BLK2, . . . , BLKn in FIG. 1A may include a memory cell array MCA having the circuit component illustrated in FIG. 1C.

Referring to FIG. 1C, the memory cell array MCA may include a plurality of cell strings CS. The memory cell array 10 may include a plurality of bit lines BL (BL1, BL2, . . . , BLm, a plurality of word lines WL (WL1, WL2, . . . , WLn-1, WLn), at least one string select line SSL, at least one ground select line GSL, and a common source line CSL. FIG. 1C illustrates the example in which each of the plurality of cell strings CS may include a ground select line GSL and two string select line SSL, but example embodiments thereof is not limited thereto. For example, each of the plurality of cell strings CS may include a string select line SSL.

Each of the plurality of cell strings CS, the string select transistor SST, the ground select transistor GST, and the plurality of memory cell transistors MC1, MC2, MC3, . . . , MCn-1, and MCn may be connected to the word line WL.

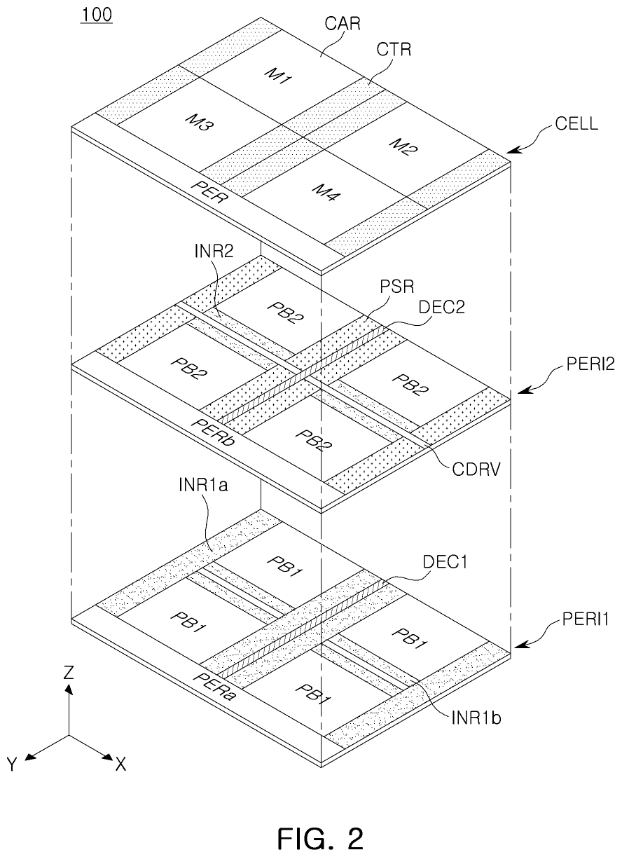

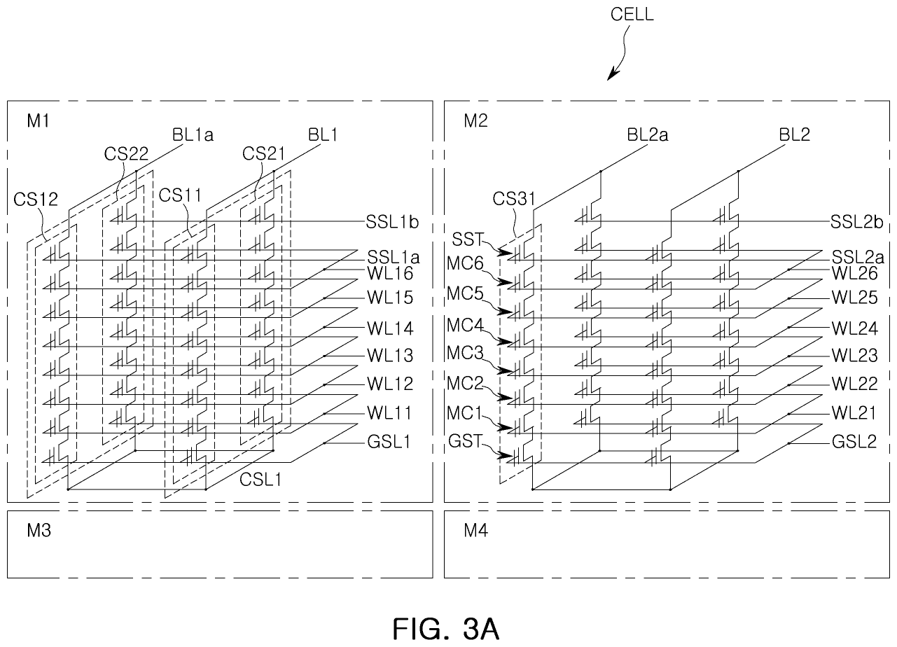

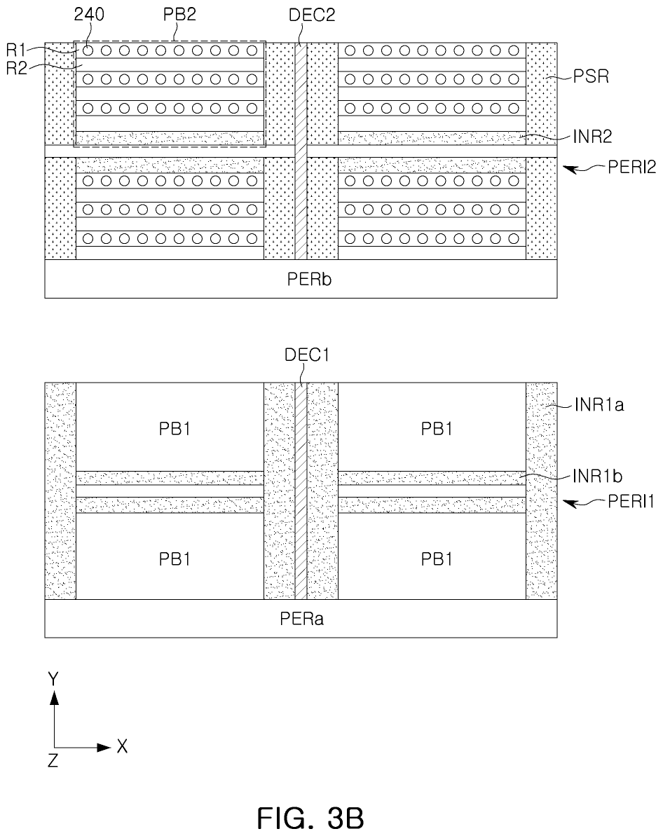

FIG. 2 is a perspective diagram illustrating a semiconductor device according to example embodiments. FIG. 3A is a circuit diagram illustrating a mat structure of a cell structure in FIG. 2 according to example embodiments. FIG. 3B is a plan diagram illustrating a first peripheral circuit structure and a second peripheral circuit structure according to example embodiments of the present disclosure.

Referring to FIG. 2, the semiconductor device 100 may include a first peripheral circuit structure PERI1, a second peripheral circuit structure PERI2, and a cell structure CELL stacked in order in the vertical direction (Z-direction).

Referring to FIGS. 2 and 3A, a semiconductor device 100 may include a plurality of mats M1, M2, M3, and M4. In an example, the cell structure CELL may include a cell array region CAR and a cell contact region CTR for each of the plurality of mats M1, M2, M3, and M4.

In the cell array region CAR, a memory cell array (e.g., the memory cell array 10 in FIG. 1A) including a plurality of memory cells may be formed. For example, in the cell array region CAR, a channel structure CH, bit lines BL, and gate electrodes (GSL, WL, SSL, or the like), which are described later, may be disposed. The cell contact region CTR may be disposed around the cell array region CAR. In the cell contact region CTR, the gate electrodes (GSL, WL, SSL, or the like) may be stacked in staircase form.

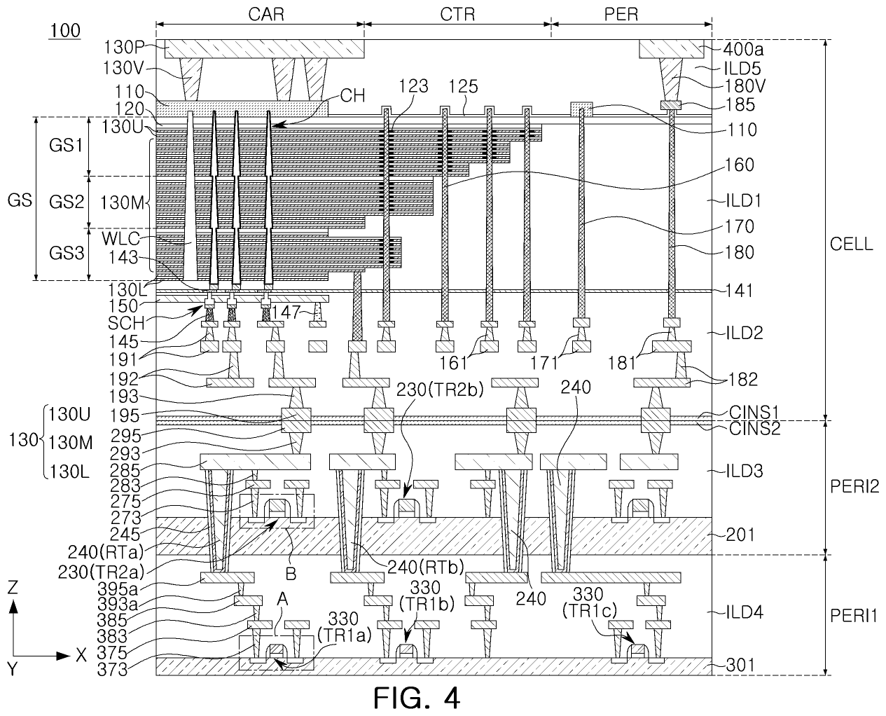

The cell structure CELL may further include a pad region PER (or a peripheral region). The pad region PER may be disposed on an external side of the cell array region CAR and the cell contact region CTR. In the pad region PER, a source contact plug (e.g., the source contact 170 in FIG. 4) and an input/output contact plug (e.g., the input/output contact 180 in FIG. 4), which will be described later, may be disposed.

The cell structure CELL may include a plurality of memory blocks for each of the plurality of mats M1, M2, M3, and M4. Each of the plurality of memory blocks may include a plurality of cell strings. For example, one of the memory blocks included in the first mat M1 may include a plurality of cell strings CS11, CS12, CS21, and CS22. A plurality of cell strings included in a mat may be formed on a plurality of planes. Although only the structures of the first and second mats M1 and M2 are illustrated in FIG. 3A, the third and fourth mats M3 and M4 may have substantially the same structure as those of the first and second mats M1 and M2.

The first and second mats M1 and M2 of the cell structure CELL may include a plurality of memory blocks, and one of the plurality of memory blocks may include a plurality of string select lines SSL1a and SSL1b to select at least one of the cell strings CS11, CS12, CS21, and CS22. For example, when a string select voltage is applied to the first string select line SSL1a, the cell strings CS11 and CS12 may be selected. When the string select voltage is applied to the second string select line SSL1b, the third and fourth cell strings CS21 and CS22 may be selected.

The first and second mats M1 and M2 may have substantially the same physical structure. For example, cell strings contained in the first mat M1 may be connected to word lines WL11 to WL16, a ground select line GSL1, and a common source line CSL1. Cell strings included in the second mat M2 may be connected to word lines WL21 to WL26, a ground select line GSL2, and a common source line CSL2. The first and second mats M1 and M2 may not share bit lines. First bit lines BL1 and BL1a may be connected exclusively to the first mat M1. Second bit lines BL2, BL2a may be connected exclusively to the second mat M2. In FIG. 3A, each of the plurality of mats M1, M2, M3, and M4 may be connected to two bit lines and six word lines, but example embodiments thereof are not limited thereto, and each of the plurality of mats M1, M2, M3, and M4 may be connected to three or more bit lines and seven or more word lines.

Each of the cell strings CS may include at least one string select transistor SST, a plurality of memory cell transistor MC1 to MC6, and a ground select transistor GST. For example, in the cell string CS31, the ground select transistor GST, the plurality of memory cell transistors MC1 to MC6, and the string select transistor SST may be formed perpendicularly to the substrate. The other cell strings may also be configured the same as the cell string CS31.

Each of the string select lines SSL1a and SSL1b may be connected only to the first mat M1. Each of the string select interconnections SSL2a and SSL2b may only be connected to the second mat M2. The plurality of mats M1, M2, M3, and M4 may independently control string select interconnection thereof, respectively, such that cell strings may be selected independently for each of the plurality of mats M1, M2, M3, and M4. For example, by independently applying a string select voltage to the first string select line SSL1a, the cell strings CS11 and CS12 may be independently selected. When a string select voltage is applied to the first string select line SSL1a, the string select voltage may turn on a string select transistor of corresponding cell strings CS11 and CS12. When the string select transistor SST is turned on, memory cells and the bit line of the cell strings CS11 and CS12 may be electrically connected to each other. Alternatively, when a non-selected voltage is applied to the first string select line SSL1a, the string select transistor of the cell strings CS11 and CS12 may be turned off, and the cell strings CS11 and CS12 may not be selected. The memory cells of the cell strings CS11 and CS12 may be electrically blocked from the first bit line BL1.

Referring to FIGS. 2 and 3B, the first and second peripheral circuit structures PERI1 and PERI2 may include page buffer regions PB1 and PB2 corresponding to one region of the cell array region CAR. The first peripheral circuit structure PERI1 may include the first page buffer regions PB1 for each of the plurality of mats M1, M2, M3, and M4. The second peripheral circuit structure PERI2 may include second page buffer regions PB2 for each of the plurality of mats M1, M2, M3, and M4. In an example, the first page buffer regions PB1 and the second page buffer regions PB2 may overlap each other in the vertical direction (Z-direction). In an example, the first page buffer region PB1 of the first mat M1 may overlap the second page buffer region PB2 of the first mat M1 in the vertical direction.

A first page buffer (e.g., the first page buffer 21a in FIG. 1B) may be disposed in the first page buffer regions PB1. A second page buffer (e.g., the second page buffer 21b in FIG. 1B) may be disposed in the second page buffer regions PB2.

In the second page buffer region PB2, the first region R1 electrically connected to the first page buffer region PB1 and the second region R2 in which the second page buffer 21b is disposed may be alternately disposed in the second direction (Y-direction). The first region R1 and the second region R2 may not overlap each other in the vertical direction (Z-direction).

The first page buffer 21a may be electrically connected to the second page buffer 21b through the first through-via 240 disposed in the first region R1.

The second peripheral circuit structure PERI2 may include a pass circuit region PSR corresponding to one region of the cell contact region CTR. A pass circuit (e.g., the pass circuit 26 in FIG. 1B) may be disposed in the pass circuit region PSR. The pass circuit region PSR may not overlap the cell array region CAR and the first and second page buffer regions PB1 and PB2. In an example, the pass circuit region PSR may be disposed on both sides of the second page buffer region PB2.

The first and second peripheral circuit structures PERI1 and PERI2 may include row decoder regions DEC1 and DEC2 corresponding to boundary regions of the plurality of mats M1, M2, M3, and M4. In an example, the row decoder regions DEC1 and DEC2 may extend in the second direction (Y-direction) between the first mat M1 and the second mat M2 and between the third mat M3 and the fourth mat M4.

The first peripheral circuit structure PERI1 may include a first row decoder region DEC1, and the second peripheral circuit structure PERI2 may include a second row decoder region DEC2 overlapping the first row decoder region DEC1.

A first row decoder (e.g., the first row decoder 22a in FIG. 1B) may be disposed in the first row decoder region DEC1. A second row decoder (e.g., the second row decoder 22b in FIG. 1B) may be disposed in the second row decoder region DEC2.

When viewed on the plane, the pass circuit region PSR may be disposed between the second page buffer region PB2 and the second row decoder region DEC2.

The second peripheral circuit structure PERI2 may include a common source line driving region CDRV corresponding to a boundary region of the plurality of mats M1, M2, M3, and M4. In an example, the common source line driving region CDRV may extend in the first direction (X-direction) between the first mat M1 and the third mat M3 and between the second mat M2 and the fourth mat M4. The common source driving region CDRV may include a region extending in the first direction (X-direction) between the first mat M1 and the third mat M3 and a region extending in the first direction (X-direction) between the second mat M2 and the fourth mat M4.

A common source line driver (e.g., the common source line driver 25 in FIG. 1B) may be disposed in the common source line driving region CDRV.

The second peripheral circuit structure PERI2 may include a second inner peripheral region INR2 between the common source line driving region CDRV and the second page buffer region PB2. The second inner peripheral region INR2 may be at least partially surrounded by the second page buffer region PB2, the pass circuit region PSR, and the common source line driving region CDRV. In an example, the second page buffer region PB2 and the second inner peripheral region INR2 may overlap the cell array region CAR.

A charge bump (not illustrated) of a voltage generator may be disposed in the second inner peripheral region INR2.

The first peripheral circuit structure PERI1 may correspond to one region of the cell contact region CTR and may include an inner peripheral region INR1a overlapping the pass circuit region PSR. The inner peripheral region INR1a may not overlap the cell array region CAR and the first and second page buffer regions PB1 and PB2. In an example, the inner peripheral region INR1a may be disposed on both sides of the first page buffer region PB1. The inner peripheral region INR1a may be disposed between the first row decoder region DEC1 and the first page buffer region PB1.

The first peripheral circuit structure PERI1 may include an inner peripheral region INR1b overlapping the second inner peripheral region INR2. In an example, the first page buffer region PB1 and the inner peripheral region INR1b may overlap the cell array region CAR.

The control logic (e.g., the control logic 23 in FIG. 1B) may be disposed in the inner peripheral region INR1a and the inner peripheral region INR1b. For example, a scheduler (not illustrated) may be disposed in the inner peripheral region INR1a and the inner peripheral region INR1b.

The first and second peripheral circuit structures PERI1 and PERI2 may include pad regions PERa and PERb overlapping the pad region PER. The pad regions PERa and PERb may be disposed on one side of the plurality of mats M1, M2, M3, and M4. The first peripheral circuit structure PERI1 may include a first pad region PERa overlapping the pad region PER. The second peripheral circuit structure PERI2 may include a second pad region PERb overlapping the first pad region PERa.

An input/output circuit (e.g., the input/output circuit 24 in FIG. 1B) may be disposed in the first pad region PERa.

In the semiconductor device according to example embodiments, a low-voltage peripheral circuit may be disposed in a first peripheral circuit structure, and a high-voltage peripheral circuit may be disposed in a second peripheral circuit structure adjacent to the cell structure, depending on a magnitude of an operating voltage of the peripheral circuit. Accordingly, integration density and a signal transmission speed may be improved.

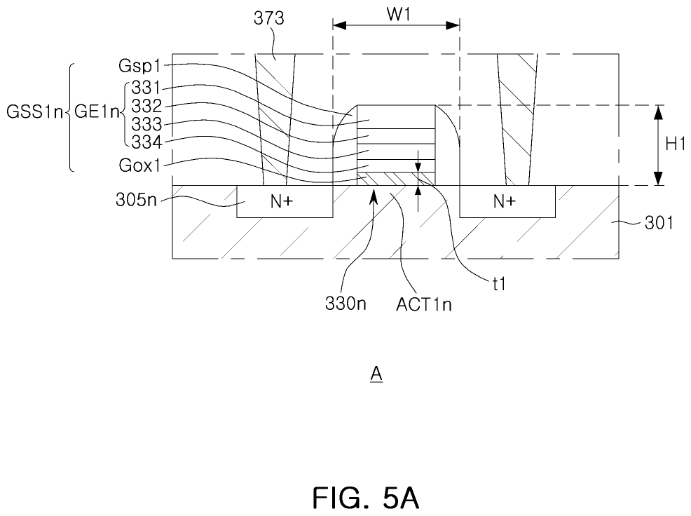

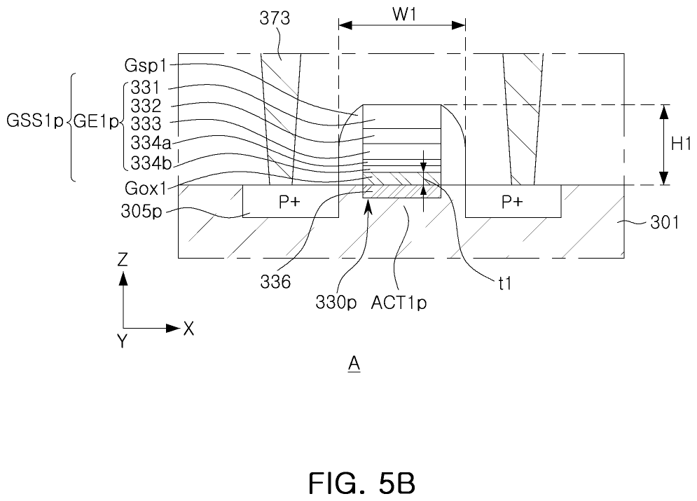

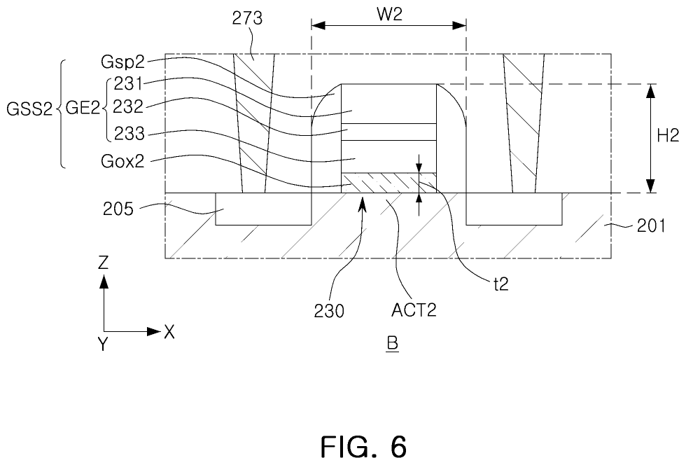

FIG. 4 is a cross-sectional diagram illustrating a semiconductor device according to example embodiments. FIG. 5A is an enlarged diagram illustrating region A in FIG. 4 according to example embodiments. FIG. 5B is an enlarged diagram illustrating region A in FIG. 4 according to example embodiments. FIG. 6 is an enlarged diagram illustrating region B in FIG. 4 according to example embodiments.

Referring to FIG. 4, a semiconductor device 100 may include a cell structure CELL and first and second peripheral circuit structures PERI1 and PERI2. In an example, the semiconductor device 100 may include the first and second peripheral circuit structures PERI1, PERI2 and the cell structure CELL, stacked in order in the vertical direction (Z-direction).

The semiconductor device 100 may include a cell structure CELL including a common source plate 110, a first peripheral circuit structure PERI1 including a first substrate 301, and a second peripheral circuit structure PERI2 including a second substrate 201.

The cell structure CELL may have a cell array region CAR, a cell contact region CTR, and a pad region PER, and may include a common source plate 110 and a gate structure GS stacked on a back surface of the common source plate 110.

The common source plate 110 may be provided in or on a portion of the cell array region CAR and the pad region PER. The common source plate 110 may not be provided in the cell contact region CTR. The common source plate 110 may be in contact with the first channel structure CH and the source contact 170. The common source plate 110 may not overlap the cell contact 160 and the input/output contact 180 in the vertical direction (Z-direction).

The common source plate 110 may be provided as a common source line (e.g., common source line GSL in FIG. 1A) of the semiconductor device. The common source plate 110 may include polysilicon or metal doped impurities, but example embodiments thereof is not limited thereto.

The upper insulating film 125 may cover or at least partially overlap a portion of the cell contact 160 and a portion of the input/output contact 180 in the vertical direction (Z-direction). In an example, the upper insulating film 125 may include a nitride or oxide insulating material.

The common source plate 110 may include a front surface and a back surface opposing the front surface. An upper interlayer insulating layer ILD5, a common source pad 130P and an input/output pad 400a may be disposed on the front surface of the common source plate 110. The gate structure GS may be disposed on the back surface of the common source plate 110.

The common source plate 110 may be electrically connected to the common source pad 130P through a common source via 130V. The common source via 130V may penetrate or extend into the upper interlayer insulating layer ILD5 and may be provided on the common source plate 110.

The cell structure CELL may include a first channel structures CH disposed to penetrate or extend into the gate structure GS in the cell array region CAR, a word line cut structure WLC extending into or penetrating the second channel structures SCH and the gate structure GS, a lower electrode 150 disposed in a lower portion of the gate structure GS, a horizontal insulating layer 141 disposed between the first channel structures CH and the second channel structures SCH, and a connection pad 143.

The cell structure CELL may include a first cell interlayer insulating layer ILD1 covering or at least partially overlapping the gate electrodes 130 in the vertical direction (Z-direction), a lower electrode 150, second channel structures SCH, a connection pad 143, a second cell interlayer insulating layer ILD2 covering or at least partially overlapping the cell interconnections 161, 171, 181, 182, 191, and 192 in the vertical direction (Z-direction), and a first bonding insulating layer CINS1 disposed below the second cell interlayer insulating layer ILD2.

The cell interconnections 161, 171, 181, 182, 191, and 192 may be disposed in the second cell interlayer insulating layer ILD2, and may include the first, second, and third cell interconnection structures 191, 192, and 171, the cell contact interconnection structure 161, and the first and second input/output interconnection structures 181 and 182.

The first and second cell interconnection structures 191 and 192 may be electrically connected to the first and second channel structures CH and SCH. The cell contact interconnection structure 161 may be electrically connected to the cell contact 160. The third cell interconnection structure 171 may be electrically connected to the source contact 170. The first and second input/output interconnection structures 181 and 182 may be electrically connected to the input/output contact 180.

The first cell interconnection structure 191, the third cell interconnection structure 171, the first input/output interconnection structure 181, and the cell contact interconnection structure 161 may be disposed on the same level in the vertical direction (Z-direction). The second cell interconnection structure 192 and the second input/output interconnection structure 182 may be disposed on the same level in the vertical direction (Z-direction).

The gate electrodes 130 may be vertically stacked and spaced apart from each other on a back surface of the common source plate 110 and may form a gate structure GS together with the interlayer insulating layers 120. The gate structure GS may include first, second, and third stack structures GS1, GS2, and GS3, vertically stacked. In example embodiments, the number of stack structures forming the gate structure GS may be varied. For example, in some example embodiments, the gate structure GS may include four or more stack structures or may include a single or double stack structure. The number of gate electrodes 130 forming each of the first, second and third stack structures GS1, GS2, and GS3 may be the same or different.

The lower electrode 150 may form string select transistors (e.g., the string select transistor SST in FIG. 1C).

The gate electrodes 130 may include upper gate electrodes 130U forming an erase transistor, memory gate electrodes 130M forming a plurality of memory cells, and lower gate electrodes 130L forming an erase transistor and/or a ground select transistor (e.g., the ground select transistor GST in FIG. 1C). The number of memory gate electrodes 130M included in the memory cells may be determined depending on capacity of the semiconductor device 100.

The gate electrodes 130 may be stacked and spaced apart from each other on the cell array region CAR, may extend at different lengths from the cell array region CAR to the cell contact region CTR and may form step structures in a staircase form. As illustrated in FIG. 4, the gate electrodes 130 may be removed at a predetermined depth from an upper portion of one of the first, second, and third stack structures GS1, GS2, and GS3.

The gate electrodes 130 may include a metal material, such as tungsten (W). In example embodiments, the gate electrodes 130 may include polycrystalline silicon or metal silicide material. The gate electrodes 130 may include the same material. In example embodiments, the gate electrodes 130 may further include a diffusion barrier, for example, the diffusion barrier may include tungsten nitride (WN), tantalum nitride (TaN), titanium nitride (TiN), or a combination thereof.

The interlayer insulating layers 120 may be disposed between the gate electrodes 130. The interlayer insulating layers 120 may be spaced apart from each other in a direction perpendicular to a back surface of the common source plate 110 (Z-direction) and may extend in the first direction (X-direction). The interlayer insulating layers 120 may include an insulating material such as silicon oxide or silicon nitride. In example embodiments, a thickness of each of the interlayer insulating layers 120 may be varied.

The first channel structures CH may penetrate or extend into the gate electrodes 130, may extend in the vertical direction (Z-direction), and may be connected to the common source plate 110. The first channel structures CH may form a memory cell string together with the second channel structures SCH, respectively, and may be spaced apart from each other in rows and columns on a back surface of the common source plate 110 in the cell array region CAR. The first channel structures CH may be disposed to form a grid pattern or in a zigzag pattern in one direction on an X-Y plane. The first channel structures CH may have a pillar shape and may have an inclined side surface having one or more widths that decrease toward the common source plate 110. At least a portion of the first channel structures CH including the first channel structures CH disposed on an end of the cell array region CAR may be dummy channel structures.

First channel structures CH may include lower, intermediate, and upper channel structures that are vertically stacked. The first channel structures CH may have a form in which the lower channel structures, the intermediate channel structures, and the upper channel structures are connected, and may have a curved portion due to a difference in width in the connection region. However, in example embodiments, the number of the channel structures stacked in the vertical direction (Z-direction) may be varied.

The second channel structure SCH may penetrate or extend into the lower electrode 150, may extend in the vertical direction (Z-direction), and may be connected to the first channel structure CH, respectively. The second channel structure SCH may be shifted in the horizontal direction from the first channel structure CH, but example embodiments thereof is not limited thereto. In an example, the second channel structure SCH may be connected to the first cell interconnection structure 191 and the second cell interconnection structure 192 connected to the first cell interconnection structure 191.

The first and second channel structures CH and SCH may be electrically connected to the first and second cell interconnection structures 191 and 192. The first and second cell interconnection structures 191 and 192 may include a conductive material. The first and second channel structures CH and SCH may be electrically connected to the second peripheral circuit structure PERI2 through the first and second cell interconnection structures 191 and 192 and the first connection structures 193 and 195. The first connection structures 193 and 195 may be disposed below the second cell interconnection structure 192 and may include a first bonding via 193 connected to the second cell interconnection structure 192 and a first bonding pad 195 connected to the first bonding via 193.

The horizontal insulating layer 141 may be disposed between the first channel structure CH and the second channel structure SCH and may extend horizontally. The horizontal insulating layer 141 may be disposed between the lower electrode 150 and the lower gate electrode 130L. The horizontal insulating layer 141 may be used as an etch stop layer when the second channel structure SCH is formed, and may also be used when the connection pads 143 are formed.

The horizontal insulating layer 141 may include an insulating material and may include a material different from that of the first and second cell interlayer insulating layers ILD1 and ILD2. The horizontal insulating layer 141 may be configured as a hydrogen blocking layer and may include a material preventing or reducing diffusion of hydrogen (H). The horizontal insulating layer 141 may include nitride, for example, at least one of SiN, SiON, SiCN, and SiOCN.

The connection pads 143 may penetrate or extend into the horizontal insulating layer 141 between the first channel structures CH and the second channel structures SCH, and may electrically connect the first channel layer of the first channel structure CH to the second channel layer of the second channel structure SCH. The connection pads 143 may be formed by partially removing the horizontal insulating layer 141, and may have upper surfaces coplanar with an upper surface of the horizontal insulating layer 141. The connection pads 143 may be partially recessed into the first channel pads of the first channel structure CH. However, the specific arrangement of the connection pads 143 may be varied in example embodiments. The connection pads 143 may include a conductive material, for example, polycrystalline silicon.

The word line cut structure WLC may have a shape of which a width may decrease toward the common source plate 110 due to a high aspect ratio. The word line cut structure WLC may include an insulating material, for example, silicon oxide, silicon nitride, or silicon oxynitride.

The cell contacts 160 may be connected to contact regions of the gate electrodes 130 in the cell contact region CTR. The cell contacts 160 may penetrate or extend into a portion of the second cell interlayer insulating layer ILD2, the first cell interlayer insulating layer ILD1 and the horizontal insulating layer 141 and may be connected to contact regions of the gate electrodes 130. The cell contacts 160 may be connected to the cell contact interconnection structure 161 disposed on the second cell interlayer insulating layer ILD2. In another example, the cell contacts 160 may be disposed to not penetrate or extend into the gate electrodes 130, and in this case, the cell contacts 160 may be connected to the contact regions of the gate electrodes 130 exposed upwardly, respectively.

The cell contacts 160 may include at least one of a conductive material, for example, tungsten (W), copper (Cu), aluminum (Al), and alloys thereof. In some example embodiments, the cell contacts 160 may include a barrier layer extending along a side surface and a bottom surface of the cell contact 160, or may have an air gap therein.

The contact insulating layers 123 may be disposed to at least partially surround side surfaces of each of the cell contacts 160 below the contact regions. The contact insulating layers 123 may be spaced apart from each other in the vertical direction (Z-direction) around each of the cell contacts 160. The contact insulating layers 123 may be disposed on substantially the same level as a level of the gate electrodes 130 in the vertical direction (Z-direction). The contact insulating layers 123 may include an insulating material, for example, silicon oxide, silicon nitride, or silicon oxynitride.

The lower contact plug 147 may be electrically connected to the lower electrode 150. The lower contact plug 147 may not penetrate or extend into the lower electrode 150. The lower contact plug 147 may be partially recessed into the lower electrode 150 from a lower surface, or may be disposed to be connected to the lower surface. The lower contact plug 147 may include a conductive material and may include the same material as that of the cell contacts 160, but an embodiment thereof is not limited thereto.

The cell structure CELL may include a source contact 170 connected to the common source plate 110 and an input/output contact 180 connected to the input/output pad 400a in the pad region PER.

The source contact 170 may be provided on a pad region PER. The source contact 170 may be formed of a conductive material such as a metal, metal compound, or polysilicon, and may be electrically connected to the common source plate 110. The source contact 170 may be electrically connected to the third cell interconnection structure 171. The third cell interconnection structure 171 may include a conductive material.

The input/output contact 180 may penetrate or extend into a portion of the second interlayer insulating layer ILD2, the first cell interlayer insulating layer ILD1 and the horizontal insulating layer 141 and may be connected to an input/output pad 400a. In an example, input/output contact 180 may be electrically connected to the input/output pad 400a through an input/output connection pad 185 and an input/output contact via 160V. The input/output pad 400a may electrically connect an external device and a semiconductor device 100 to each other. The input/output pad 400a may include a conductive material.

The input/output contact 180 may be electrically connected to the first and second input/output interconnection structures 181 and 182. The first and second input/output interconnection structures 181 and 182 may include a conductive material.

The input/output contact 180 may be electrically connected to the first peripheral circuit structure PERI1 through the first and second input/output interconnection structures 181 and 182 and the first connection structures 193 and 195.

The first bonding insulating layer CINS1 and the first bonding pad 195 may be disposed below the cell interconnections 161, 171, 181, 182, 191, and 192. In an example, the first bonding insulating layer CINS1 may be disposed below the second cell interlayer insulating layer ILD2. The first bonding pad 195 may be buried in a lower surface of the first bonding insulating layer CINS1.

The second peripheral circuit structure PERI2 may be disposed in a lower portion of the cell structure CELL.

The second peripheral circuit structure PERI2 may include a second substrate 201, a second peripheral circuit 230 disposed on the second substrate 201, second peripheral interconnections 273, 275, 283, and 285 connected to the second peripheral circuit 230, and second connection structures 293 and 295 electrically connected to the second peripheral interconnections 273, 275, 283, 285.

The second peripheral circuit structure PERI2 may further include a second peripheral interlayer insulating layer ILD3 covering or at least partially overlapping the second peripheral circuit 230, the second peripheral interconnections 273, 275, 283, and 285, and the second connection structure 293 and 295 in the vertical direction (Z-direction), and a second bonding insulating layer CINS2 disposed on the second peripheral interlayer insulating layer ILD3.

The second substrate 201 may include a semiconductor material, such as a group IV semiconductor, a group III-V compound semiconductor, or a group II-VI compound semiconductor. The second substrate 201 may be provided as a bulk wafer or an epitaxial layer.

The second peripheral circuit 230 may include a planar transistor on the second substrate 201. The second peripheral circuit 230 may have a second driving voltage (e.g., a relatively higher driving voltage). A magnitude of the second driving voltage of the second peripheral circuit 230 may be greater than that of the first driving voltage of the first peripheral circuit 330.

The second peripheral circuit 230 may include a second page buffer (e.g., the second page buffer 21b in FIG. 1B), a second row decoder (e.g., the second row decoder 22b in FIG. 1B), and a pass circuit (e.g., the pass circuit 26 in FIG. 1B). For example, the second peripheral circuit 230 may include a peripheral circuit TR2a overlapping the cell array region CAR, and may include a peripheral circuit TR2b overlapping the cell contact region CTR. The peripheral circuit TR2a and the peripheral circuit TR2b may have the same size.

The peripheral circuit TR2a may provide or include a second page buffer 21b connected to a bit line BL of the cell structure CELL. The peripheral circuit TR2b may provide or include a second row decoder 22b (or the pass circuit, for example, the pass circuit 26 in FIG. 1B) connected to a word line WL of the cell structure CELL.

The second peripheral circuit 230 may be disposed on the second substrate 201 to face the cell structure CELL.

The second peripheral interconnections 273, 275, 283, and 285 may be electrically connected to the second peripheral circuit 230. The second peripheral interconnections 273, 275, 283, and 285 may include the second peripheral contact plugs 273, 283 and the second peripheral contact interconnections 275 and 285.

The second peripheral contact plugs 273 and 283 may include a peripheral contact plug 273, and a peripheral contact plug 283. The second peripheral contact interconnections 275 and 285 may include a peripheral contact interconnection 275 disposed between the peripheral contact plug 273 and the peripheral contact plug 283, and a peripheral contact interconnection 285 disposed between the peripheral contact plug 283 and the second connection structures 293 and 295. The peripheral contact interconnection 285 may be disposed between the second bonding via 293 and the peripheral contact plug 283.

The second peripheral contact plugs 273 and 283 may have a cylindrical shape, and the second peripheral contact interconnections 275 and 285 may have a line or linear shape. An electrical signal may be applied to the second peripheral circuit 230 by the second peripheral interconnections 273, 275, 283, and 285. The second peripheral contact interconnections 275 and 285 may be connected to the second peripheral contact plugs 273 and 283, may have a line or linear shape, and may be disposed as a plurality of layers. The second peripheral interconnections 273, 275, 283, and 285 may include a conductive material, for example, tungsten (W), copper (Cu), aluminum (Al), or the like, and each of the components may further include a diffusion barrier. In an example, the number of layers of the second peripheral interconnections 273, 275, 283, and 285 may be varied in various example embodiments.

The second peripheral interlayer insulating layer ILD3 may be disposed to cover or at least partially overlap the second peripheral circuit 230 and the second peripheral interconnections 273, 275, 283, and 285 disposed on the second substrate 201 in the vertical direction (Z-direction). The second peripheral interlayer insulating layer ILD3 may include a plurality of insulating layers formed in different processes. The second peripheral interlayer insulating layer ILD3 may include an insulating material. The second bonding insulating layer CINS2 may be disposed on the second peripheral interlayer insulating layer ILD3. The second connection structures 293 and 295 may be disposed on the second peripheral interconnections 273, 275, 283, and 285. The second bonding pad 295 may be buried in an upper surface of the second bonding insulating layer CINS2. The second bonding via 293 may be disposed in a lower portion of the second bonding pad 295 and may be connected to the second bonding pad 295.

The cell structure CELL and the second peripheral circuit structure PERI2 may be bonded to each other by the first and second bonding pads 195 and 295 and the first and second bonding insulating layers CINS1 and CINS2. The bonding between the first and second bonding pads 195 and 298 may be copper (Cu)-copper (Cu) bonding, and the bonding between the first and second bonding insulating layers CINS1 and CINS2 may be dielectric-dielectric bonding such as SiCN—SiCN bonding, for example. The cell structure CELL and the second peripheral circuit structure PERI2 may be bonded to each other by hybrid bonding including copper (Cu)-copper (Cu) bonding and dielectric-dielectric bonding.

The cell structure CELL and the second peripheral circuit structure PERI2 may be connected to each other through the first connection structure 193 and 195 and the second connection structure 293 and 295.

The first peripheral circuit structure PERI1 may be disposed below the second peripheral circuit structure PERI2.

The first peripheral circuit structure PERI1 may include a first substrate 301, a first peripheral circuit 330 disposed on the first substrate 301, and first peripheral interconnections 373, 375, 383, 385, 393a, and 395a connected to the first peripheral circuit 330. The first peripheral circuit structure PERI1 may include a first peripheral interlayer insulating layer ILD4 covering or at least partially overlapping the first peripheral circuit 330 and the first peripheral interconnections 373, 375, 383, 385, 393a, and 395a in the vertical direction (Z-direction).

The first substrate 301 may include a semiconductor material, such as a group IV semiconductor, a group III-V compound semiconductor, or a group II-VI compound semiconductor. The first substrate 301 may be provided as a bulk wafer or an epitaxial layer.

The first substrate 301 may have a first height or thickness in the vertical direction (Z-direction). The second substrate 201 may have a second height or thickness in the vertical direction (Z-direction), and the second height/thickness may be greater than the first height/thickness.

The first peripheral circuit 330 on the first substrate 301 may include a planar transistor. The first peripheral circuit 330 may have a first driving voltage (e.g., a relatively lower driving voltage).

The first peripheral circuit 330 may include a first page buffer (e.g., the first page buffer 21a in FIG. 1B), a first row decoder (e.g., the first row decoder 22a in FIG. 1B), and a control logic (e.g., the control logic 23 in FIG. 1B). For example, the first peripheral circuit 330 may include a peripheral circuit TR1a overlapping the memory cell array region CAR, and a peripheral circuit TR1b overlapping the cell contact region CTR.

The peripheral circuit TR1a may provide or include a first page buffer 21a connected to a bit line BL of the cell structure CELL through a first through-via RTa. The peripheral circuit TR1b may provide or include a first row decoder 22a connected to a word line WL of the cell structure CELL through a first through-via RTb.

The first peripheral circuit 330 may be disposed on the first substrate 301 toward the second peripheral circuit structure PERI2.

The first peripheral interconnections 373, 375, 383, 385, 393a, and 395a may be electrically connected to the first peripheral circuit 330. The first peripheral interconnections 373, 375, 383, 385, 393a, and 395a may include first peripheral contact plug 373, 383, and 393a and first peripheral contact interconnections 375, 385, and 395a.

The first peripheral contact plug 373, 383, and 393a may include a peripheral contact plug 373, a peripheral contact plug 383, and a peripheral contact plug 393a. The first peripheral contact interconnections 375, 385, and 395a may include a peripheral contact interconnection 375 disposed between the peripheral contact plug 373 and the peripheral contact plug 383, a peripheral contact interconnection 385 disposed between the peripheral contact plug 383 and the peripheral contact plug 393a, and a peripheral contact interconnection 395a disposed on the peripheral contact plug 393a.

The first peripheral contact plugs 373, 383, and 393a may have a cylindrical shape, and the first peripheral contact interconnections 375, 385, and 395a may have a line shape. An electrical signal may be applied to the first peripheral circuit 330 by the first peripheral interconnections 373, 375, 383, 385, 393a, and 395a. The first peripheral interconnections 373, 375, 383, 385, 393a, and 395a may include a conductive material, and each component may further include a diffusion barrier. In an example, the number of layers of the first peripheral interconnections 373, 375, 383, 385, 393a, and 395a may be varied in various example embodiments.

The first peripheral interlayer insulating layer ILD4 may be disposed to cover or at least partially overlap the first peripheral circuit 330 and the first peripheral interconnections 373, 375, 383, 385, 393a, and 395a disposed on the first substrate 301 in the vertical direction (Z-direction). An upper surface of the first peripheral interlayer insulating layer ILD4 may be in contact with a lower surface of the second substrate 201 of the second peripheral circuit structure PERI2. The first peripheral interlayer insulating layer ILD4 may include a plurality of insulating layers formed in different processes. The first peripheral interlayer insulating layer ILD4 may include an insulating material.

The semiconductor device 100 may further include a first through-via 240 penetrating or extending into the second substrate 201 and electrically connecting the first peripheral interconnections 373, 375, 383, 385, 393a, and 395a to the second peripheral interconnections 273, 275, 283, and 285.

The first through-via 240 may penetrate or extend into a portion of the first and second peripheral interlayer insulating layers ILD3, ILD4 and the second substrate 201, and may electrically connect the first peripheral interconnections 373, 375, 383, 385, 393a, and 395a to the second peripheral interconnections 273, 275, 283, and 285. The first through-via 240 may be provided between the peripheral contact interconnection 285 and the peripheral contact interconnection 395a. The first through-via 240 may be shaped such that a width may decrease toward the first peripheral circuit structure PERI1.

The semiconductor device 100 may further include a via insulating film 245 at least partially surrounding a side surface of the first through-via 240. The via insulating film 245 may include an insulating material, for example, silicon oxide. The first through-via 240 may include a through-electrode and a barrier layer disposed between the through-via and the via insulating film 245. The barrier layer may cover or at least partially overlap a sidewall of the through-electrode and a lower surface of the through-electrode in the first direction (X-direction).

The first peripheral circuit structure PERI1 and the second peripheral circuit structure PERI2 may be a through-silicon via (TSV) structure. The TSV structure may be formed by forming a lower chip including the first peripheral circuit structure PERI1, forming an intermediate chip including the second peripheral circuit structure PERI2, disposing an intermediate chip on a lower chip, forming a through-via (e.g., the first through-via 240 in FIG. 4) penetrating or extending into a portion of a lower chip and the intermediate chip, and in the structure, the lower chip may electrically connect the intermediate chip through a through-via.

FIG. 5A is an enlarged diagram illustrating region A in FIG. 4 according to example embodiments. FIG. 5B is an enlarged diagram illustrating region A in FIG. 4 according to example embodiments. FIG. 6 is an enlarged diagram illustrating region B in FIG. 4 according to example embodiments.

FIG. 5A illustrates an example in which the first peripheral circuit (e.g., the first peripheral circuit 330 in FIG. 4) is configured as a low-voltage NMOS circuit device 330n, and FIG. 5B illustrates an example in which the first peripheral circuit 330 is configured as a low-voltage PMOS circuit device 330p.

Referring to FIG. 5A, the first peripheral circuit 330n may be disposed on the first peripheral active region ACT1n of the first substrate 301. The first peripheral circuit 330n may include the first gate stack GSS1n and the first source/drain region 305n.

The first peripheral active region ACT1n may be formed in the first substrate 301. The first peripheral active region ACT1n may include impurities of the first conductivity type. The first peripheral active region ACT1n may be doped with P-type impurities.

The first source/drain region 305n may include an impurity region of a conductivity type opposite to that of the first peripheral active region ACT1n. In an example, the first source/drain region 305n may include a region doped with N-type impurities.

The first gate stack GSS1n may include a first gate insulating film Gox1, a first gate electrode GE1n, and a first gate spacer Gsp1 covering or overlapping sidewalls of the first gate insulating film Gox1 and the first gate electrode GE1n in the first direction (X-direction). The first source/drain region 305n may include a pair of impurity regions formed in the first peripheral active region ACT1n of the first substrate 301 on both sides of the first gate stack GSS1n.

The first gate insulating film Gox1 may include a high-K material. The high-κ material may refer to a dielectric material having a higher dielectric constant than that of a silicon oxide film (SiO2). The high-material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The first gate electrode GE1n may include a gate metal pattern 334, a first gate conductive pattern 333, and gate metal patterns 331, 332 stacked in the vertical direction (Z-direction) on the first gate insulating film Gox1. In an example, the gate metal pattern 334 may include an N-type metal layer. The first gate conductive pattern 333 may include a poly-silicon (Poly-Si) layer. The gate metal patterns 331 and 332 may include different metals. For example, the metal layer 331 may include titanium nitride (TiN) or TSN (Ti—Si—N), and the metal layer 332 may include tungsten (W).

The first gate spacer Gsp1 may be provided as a pair of spacers on sidewalls of the first gate stack GSS1n. The first gate spacer Gsp1 may be formed of an oxide film, a nitride film, an oxynitride film, or a combination thereof.

Referring to FIG. 5B, the first peripheral circuit 330p may include the first gate stack GS1p and first source/drain region 305p. The first peripheral circuit 330p may be disposed on the first peripheral active region ACT1p of the first substrate 301.

The first peripheral active region ACT1p may be formed in the first substrate 301. The first peripheral active region ACT1p may include impurities of the first conductivity type. The first peripheral active region ACT1p may be doped with N-type impurities.

The first source/drain region 305p may include an impurity region of a conductivity type opposite to that of the first peripheral active region ACT1p. In an example, the first source/drain region 305p may include a region doped with P-type impurities.

The first gate stack GS1p may include a first gate insulating film Gox1, a first gate electrode GE1p, and a first gate spacer Gsp1 covering or at least partially overlapping sidewalls of the first gate insulating film Gox1 and the first gate electrode GE1p in the first direction (X-direction). The first source/drain region 305p may include a pair of impurity regions formed in the first peripheral active region ACT1p of the first substrate 301 on both sides of the first gate stack GS1p.

The first gate electrode GE1p may include a 1-1b gate metal pattern 334b stacked in the vertical direction (Z-direction) on the first gate insulating film Gox1, a gate metal pattern 334a, a first gate conductive pattern 333, and gate metal patterns 331, 332. In an example, the gate metal pattern 334b may include a first conductive metal layer, and the gate metal pattern 334a may include a second conductive metal layer different from the first conductive. For example, the gate metal pattern 334b may include a P-type metal layer, and the gate metal pattern 334a may include an N-type metal layer. The first gate conductive pattern 333 may include a poly-silicon (Poly-Si) layer. The gate metal patterns 331 and 332 may include different metals. For example, the metal layer 331 may include titanium nitride (TiN) or TSN (Ti—Si—N), and the metal layer 332 may include tungsten (W).

The first gate electrode GE1p may further include a metal-semiconductor compound layer 336 (or a metal-semiconductor channel layer) provided in the first peripheral active region ACT1p between the first source/drain regions 305p. The metal-semiconductor compound layer 336 may include a metal element and a semiconductor element. For example, the metal-semiconductor compound layer 336 may include silicon-germanium (SiGe).

Referring to FIG. 6, the second peripheral circuit 230 may be disposed on the second peripheral active region ACT2 of the second substrate 201. The second peripheral circuit 230 may include a second gate stack GSS2 and a second source/drain region 205.

A second peripheral active region ACT2 may be formed in the second substrate 201. The second peripheral active region ACT2 may include impurities having a first conductivity type. The second source/drain region 205 may include an impurity region having a second conductivity type different from the first conductivity type of the second peripheral active region ACT2. For example, when the second peripheral active region ACT2 is doped with P-type impurities, the second source/drain region 205 may include a region doped with N-type impurities, and when the second peripheral active region ACT2 is doped with N-type impurities, the second source/drain region 205 may include a region doped with P-type impurities.

The second gate stack GSS2 may include a second gate insulating film Gox2, a second gate electrode GE2, and a second gate spacer Gsp2 covering or at least partially overlapping sidewalls of the second gate insulating film Gox2 and the second gate electrode GE2 in the first direction (X-direction).

The second gate insulating film Gox2 may include a silicon oxide film (SiO2, SiON, GeON, and GeSiO).

The second gate electrode GE2 may include a second gate conductive pattern 233 and a second gate metal patterns 231 and 232 stacked in the vertical direction (Z-direction) on the second gate insulating film Gox2.

The second gate conductive pattern 233 may include a poly-silicon (Poly-Si) layer. The second gate metal patterns 231 and 232 may include different metals. For example, the metal layer 231 may include titanium nitride (TiN) or TSN (Ti—Si—N), and the metal layer 232 may include tungsten (W).

The second gate spacer Gsp2 may be provided as a pair of spacers on sidewalls of the second gate stack GSS2. The second gate spacer GSS2 may be formed of an oxide film, a nitride film, an oxynitride film, or a combination thereof.

Referring to FIGS. 5A, 5B and 6, the first gate stack GSS1n and GSS1p of the first peripheral circuit 330n and 330p may have a first height (or thickness) H1 in the vertical direction (Z-direction), and the second gate stack of the second peripheral circuit 230 GSS2 may have a second height (or thickness) H2 greater than the first height H1. In an example, the first gate insulating film Gox1 of the first gate stack GSS1n and GSS1p may have a first thickness t1 in the vertical direction (Z-direction), and the second gate insulating film Gox2 of the second gate stack GSS2 may have a second thickness t2 greater than the first thickness t1. For example, the first thickness t1 may be less than about 60 Å, and the second thickness t2 may be about 60 Å or more and about 460 Å or less.

The first gate insulating film Gox1 may have a first dielectric constant, and the second gate insulating film Gox2 may have a second dielectric constant smaller than the first dielectric constant.

A channel width of the first peripheral circuit 330n and 330p may have a first width W1 in the first direction (X-direction), and a channel width of the second peripheral circuit 230 may have a second width W2 in the first direction (X-direction) greater than the first width W1.

In the semiconductor devices according to example embodiments, by dividing by a magnitude of a driving voltage, the second peripheral circuit 230 having a relatively higher driving voltage may be disposed relatively adjacent to the cell structure CELL (e.g., closer to the cell structure CELL compared to the first peripheral circuit 330), and the first peripheral circuit 330 having a relatively lower driving voltage may be relatively spaced apart from the cell structure CELL (e.g., further from the cell structure CELL compared to the second peripheral circuit 230). As such, the semiconductor devices of the present disclosure provide an efficient electrical path and efficiently physical arrangement of the first and second peripheral circuits 230 and 330 having different sizes, thereby improving integration density.

FIG. 7 is a cross-sectional diagram illustrating the semiconductor device in FIG. 2 according to example embodiments.

The components other than the third peripheral circuit 335 of the first peripheral circuit structure PERI1 and the fourth peripheral circuit 235 of the second peripheral circuit structure PERI2 of the semiconductor device 100a may be the same as or similar to the components of the semiconductor device 100 in FIG. 4.

The first peripheral circuit structure PERI1 may include the first peripheral circuit 330 and a third peripheral circuit 335 having a size different from that of the first peripheral circuit 330. In an example, a size of the first peripheral circuit 330 may be smaller than that of the third peripheral circuit 335. The first peripheral circuit 330 may have a first driving voltage, and the third peripheral circuit 335 may have a third driving voltage greater than the first driving voltage.

The first peripheral circuit 330 may be disposed on the cell array region CAR. The third peripheral circuit 335 may be disposed in or on the cell contact region CTR. In an example, the first peripheral circuit 330 may provide or include a first page buffer (e.g., the first page buffer 21a in FIG. 1B). The third peripheral circuit 335 may provide or include a first row decoder (e.g., the first row decoder 22a in FIG. 1B) (or a control logic, for example, the control logic 23 in FIG. 1B)).

The second peripheral circuit structure PERI2 may include a second peripheral circuit 230 and a fourth peripheral circuit 235 having a size different from that of the second peripheral circuit 230. In an example, a size of the second peripheral circuit 230 may be greater than that of the fourth peripheral circuit 235. The second peripheral circuit 230 may have a second driving voltage, and the fourth peripheral circuit 235 may have a fourth driving voltage smaller than the second driving voltage.

The second driving voltage of the second peripheral circuit 230 and the fourth driving voltage of the fourth peripheral circuit 235 may be greater than a third driving voltage of the third peripheral circuit 335.

The second peripheral circuit 230 may be disposed on the cell array region CAR. The fourth peripheral circuit 235 may be disposed in or on the cell contact region CTR. In an example, the second peripheral circuit 230 may provide a second page buffer (e.g., second page buffer 21b (or the common source line driver) in FIG. 1B (e.g., the common source line driver 25 in FIG. 1B)). The fourth peripheral circuit 235 may provide a second row decoder (e.g., the second row decoder 22b in FIG. 1b) may be provided.

The third peripheral circuit 335 and the fourth peripheral circuit 235 may have the same size. That is, a height or thickness of a gate stack of the third and second peripheral circuits 335 and 235 may be greater than that of a gate stack of the first peripheral circuit 330 and smaller than a height or thickness of the gate stack of the second peripheral circuit 230. In another example, a size of the fourth peripheral circuit 235 may be greater than a size of the third peripheral circuit 335.

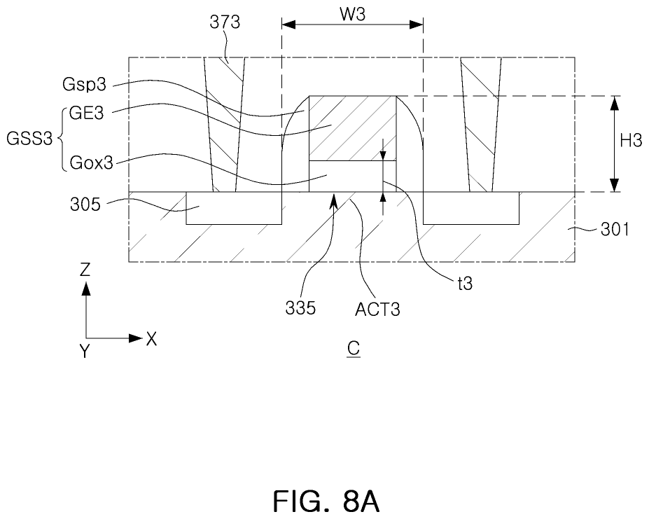

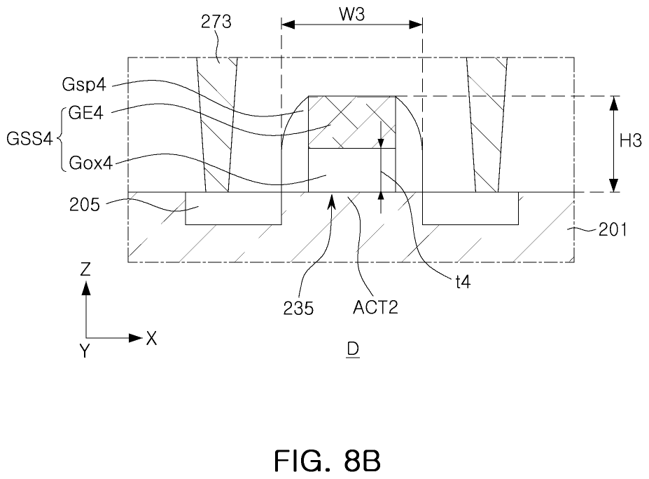

FIG. 8A is an enlarged diagram illustrating C region in FIG. 7 according to example embodiments. FIG. 8B is an enlarged diagram illustrating D region in FIG. 7 according to example embodiments.

Referring to FIG. 8A, a third peripheral circuit 335 may be disposed on a third active region ACT3 of a first substrate 301. The third peripheral circuit 335 may include a third gate stack GSS3 and a third source/drain region 305.

A third peripheral active region ACT3 may be formed in the first substrate 301. The third peripheral active region ACT3 may include impurities having a first conductivity type. The third source/drain region 305 may include an impurity region having a second conductivity type different from the first conductivity type of the third peripheral active region ACT3. For example, when the third peripheral active region ACT3 is doped with P-type impurities, the third source/drain region 305 may include a region doped with N-type impurities, and when the third peripheral active region ACT3 is doped with n-type impurities, the third source/drain region 305 may include a region doped with p-type impurities.

The third gate stack GSS3 may include a third gate insulating film Gox3, a third gate electrode GE3, and a third gate spacer Gsp3 covering or at least partially overlapping sidewalls of the third gate insulating film Gox3 and the third gate electrode GE3 in the first direction (X-direction).

The third gate stack GSS3 may include the same components as the components of the first gate stack GS1p in FIG. 5A or the components of the first gate stack GSS1n in FIG. 5B.

Referring to FIG. 8B, the fourth peripheral circuit 235 may be disposed on the second active region ACT2 of the second substrate 201. The fourth peripheral circuit 235 may include a fourth gate stack GSS4 and a second source/drain region 205.

The fourth gate stack GSS4 may include a fourth gate insulating film Gox4, a fourth gate electrode GE4, and a third gate spacer Gsp4 covering or at least partially overlapping sidewalls of the fourth gate insulating film Gox4 and the fourth gate electrode GE4 in the first direction (X-direction).

The fourth gate stack GSS4 may include the same components as the components of the second gate stack GSS2 in FIG. 6.

Referring to FIGS. 5A, 5B, 6, 8A and 8B, a third height (or thickness) H3 of the third gate stack GSS3 of the third peripheral circuit 335 and the fourth gate stack GSS4 of the fourth peripheral circuit 235 in the vertical direction (Z-direction) may be configured. The third height (or thickness) H3 may be greater than the first height H1 of the first gate stack GS1p, GSS1n and may be smaller than the second height H2 of the second gate stack GSS2.

The third thickness (or height) t3 in the vertical direction (Z-direction) of the third gate insulating film Gox3 of the third gate stack GSS3 may be smaller than the fourth thickness (or height) t4 of the fourth gate insulating film Gox4 of the fourth gate stack GSS4. In an example, the third thickness t3 of the third gate insulating film Gox3 may be greater than the first thickness t1 of the first gate insulating film Gox1. The fourth thickness t4 of the fourth gate insulating film Gox4 may be smaller than the thickness t2 of the second gate insulating film Gox2.

The third gate insulating film Gox3 may have a first dielectric constant, and the fourth gate insulating film Gox4 may have a second dielectric constant smaller than the first dielectric constant. In an example, the third gate insulating film Gox3 may have substantially the same dielectric constant as that of the first gate insulating film (e.g., the first gate insulating film Gox1 in FIGS. 5A and 5B). The fourth gate insulating film Gox4 may be substantially the same as a dielectric constant of the second gate insulating film (e.g., the second gate insulating film Gox2 in FIG. 6).

A channel width of the third peripheral circuit 335 and the fourth peripheral circuit 235 may have a third width W3. The third width W3 may be greater than the first width W1 of the first peripheral circuit 330 and may be smaller than the second width W2 of the second peripheral circuit 230.

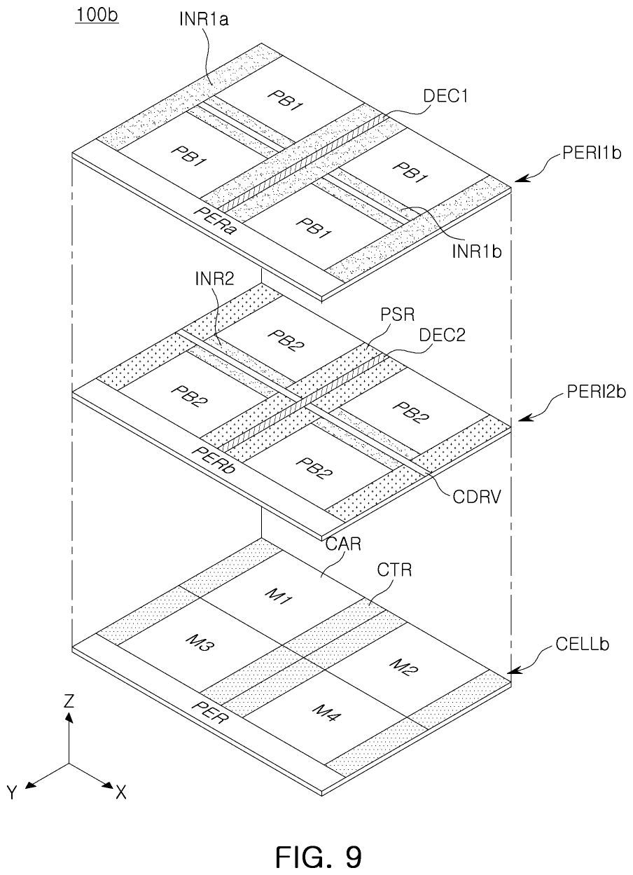

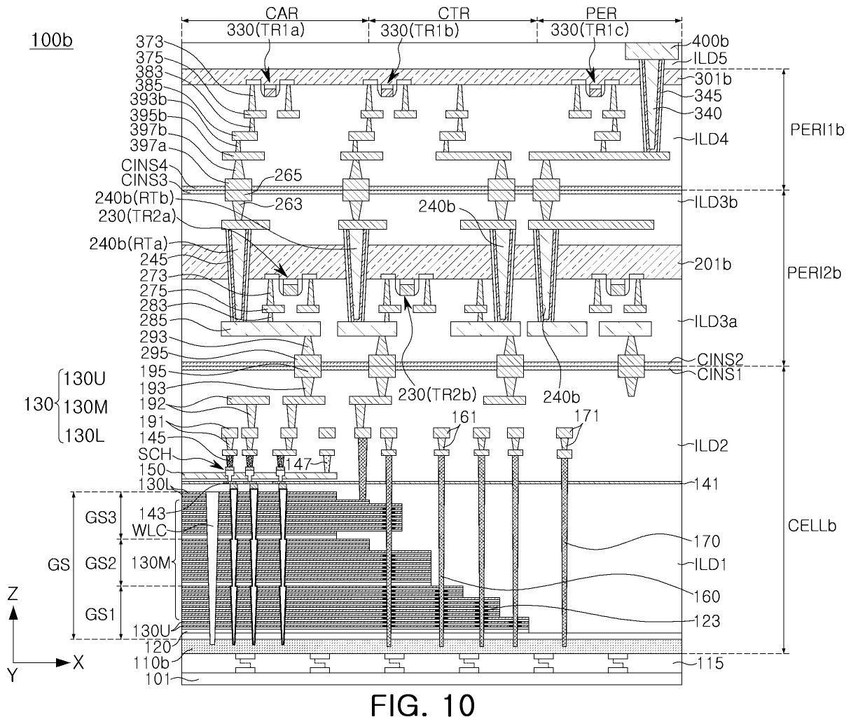

FIG. 9 is a perspective diagram illustrating a semiconductor device according to example embodiments. FIG. 10 is a cross-sectional diagram illustrating a semiconductor device according to example embodiments.

In the semiconductor device 100b, the cell structure CELLb may be disposed below the second peripheral circuit structure PERI2b. In an example, the semiconductor device 100b may include a cell structure CELLb, a second peripheral circuit structure PERI2b, and a first peripheral circuit structure PERI1b stacked in order in the vertical direction (Z-direction).

The semiconductor device 100b may include a cell structure CELLb including a common source plate 110b, a first peripheral circuit structure PERI1b including a first substrate 301b, and a second peripheral circuit structure PERI2b including a second substrate 201b.

The common source plate 110b may be provided in or on the cell array region CAR, the cell contact region CTR and the pad region PER. The common source plate 110b may be in contact with the first channel structure CH, the cell contact 160, and the source contact 170. An insulating film (not illustrated) may be disposed on a portion of the cell contact 160 in contact with the common source plate 110b.

The common source plate 110b may include a front surface and a back surface opposing the front surface. The gate structure GS may be disposed on the front surface of common source plate 110b. A base substrate 101 and an interconnection structure layer 115 disposed on the base substrate 101 may be disposed on the back surface of the common source plate 110b.

The base substrate 101 may include a semiconductor material, such as a group IV semiconductor, a group III-V compound semiconductor, or a group II-VI compound semiconductor. The second substrate 201 may be provided as a bulk wafer or an epitaxial layer.

The interconnection structure layer 115 may be configured as a redistribution structure layer for the cell interconnections 161, 171, 191, and 192 disposed in the cell structure CELLb.

The memory cell structure CELLb may include a first cell interlayer insulating layer ILD1 covering or at least partially overlapping the gate electrodes 130 in the vertical direction (Z-direction), a lower electrode 150, second channel structures SCH, a connection pad 143, a second cell interlayer insulating layer ILD2 covering or at least partially overlapping cell interconnections 161, 171, 181, 182, 191, and 192 in the vertical direction (Z-direction), and a first bonding insulating layer CINS1 disposed on the second cell interlayer insulating layer ILD2.

The first bonding insulating layer CINS1 and the first bonding pad 195 may be disposed on the cell interconnections 161, 171, 191, and 192. In an example, the first bonding insulating layer CINS1 may be disposed on the second cell interlayer insulating layer ILD2. The first bonding pad 195 may be buried on an upper surface of the first bonding insulating layer CINS1.

The second peripheral circuit structure PERI2b may be disposed on the memory cell structure CELLb.

The second peripheral circuit structure PERI2b may include a second substrate 201b, a second peripheral circuit 230 disposed on a lower surface of the second substrate 201b, second peripheral interconnections 273, 275, 283, 285 connected to the second peripheral circuit 230, and a second connection structure 293, 295 electrically connected to the second peripheral interconnections 273, 275, 283, 285. The second peripheral circuit structure PERI2b may further include third connection structures 263 and 265 disposed on an upper surface of the second substrate 201b.

The second peripheral circuit structure PERI2b may further include a peripheral interlayer insulating layer ILD3a disposed on a lower surface of the second substrate 201b and covering or at least partially overlapping the second peripheral circuit 230 in the vertical direction (Z-direction), the second peripheral interconnections 273, 275, 283, 285, and the second connection structure 293, 295, and a peripheral interlayer insulating layer ILD3b disposed on an upper surface of the second substrate 201b and the third bonding insulating layer CINS3 disposed on the peripheral interlayer insulating layer ILD3b.

The second substrate 201b may include a front surface opposing the first peripheral circuit structure PERI1b and a back surface opposing the cell structure CELLb.

Third connection structures 263 and 265 may be disposed on the front surface of the second substrate 201b. The third connection structures 263 and 265 may include a third bonding via 263 and a third bonding pad 265. The third bonding pad 265 may be buried in an upper surface of the third bonding insulating layer CINS3.

The second peripheral circuit structure PERI2b may further include a first through-via 240b penetrating or extending into the second substrate 201b and electrically connecting the third connection structures 263 and 265 to the second peripheral interconnections 273, 275, 283, and 285.

The first through-via 240b may penetrate or extend into a portion of the peripheral interlayer insulating layer ILD3a, a portion of the peripheral interlayer insulating layer ILD3b, and the second substrate 201b, and may electrically connect the third connection structures 263, 265 disposed on a front surface of the second substrate 201b to the second peripheral interconnections 273, 275, 283, and 285 disposed on a back surface of the second substrate 201b. The second through-via 240b may be disposed between the third bonding via 263 and the peripheral contact interconnection 285. The first through-via 240b may have a shape of which a width may decrease toward the cell structure CELLb.

The first peripheral circuit structure PERI1b may be disposed on the second peripheral circuit structure PERI2b.

The first peripheral circuit structure PERI1b may include a first substrate 301b, a first peripheral circuit 330 disposed on a lower surface of first substrate 301b, first peripheral interconnections 373, 375, 383, 385, 393b, and 395b connected to the first peripheral circuit 330, and fourth connection structure 397a and 397b disposed below the first peripheral interconnections 373, 375, 383, 385, 393b, and 395b.

The first peripheral circuit structure PERI1b may include a first peripheral interlayer insulating layer ILD4 covering or at least partially overlapping the first peripheral circuit 330 and the first peripheral interconnections 373, 375, 383, 385, 393b, and 395b in the vertical direction (Z-direction), and an upper interlayer insulating layer ILD5 disposed on an upper surface of the first substrate 301b.

The first peripheral interconnections 373, 375, 383, 385, 393b, and 395b may be electrically connected to the first peripheral circuit 330. The first peripheral interconnections 373, 375, 383, 385, 393b, and 395b may include a first peripheral contact plug 373, 383, and 393b and first peripheral contact interconnections 375, 385, and 395b.

The first peripheral contact plug 373, 383, and 393b may include peripheral contact plugs 373, a peripheral contact plug 383, and a peripheral contact plug 393b. The first peripheral contact interconnections 375, 385, and 395b may include a peripheral contact interconnection 375 disposed between the peripheral contact plug 373 and the peripheral contact plug 383, a peripheral contact interconnection 385 disposed between the peripheral contact plug 383 and the peripheral contact plug 393b, and a peripheral contact interconnection 395b disposed below the peripheral contact plug 393b.

The fourth connection structures 397a and 397b may be disposed below the first peripheral interconnections 373, 375, 383, 385, 393b, and 395b. The fourth connection structure 397a, 397b may include a fourth bonding via 397b disposed below the peripheral contact interconnection 395b and connected to the first peripheral interconnections 373, 375, 383, 385, 393b, and 395b, and a fourth bonding pad 397a connected to the fourth bonding via 397b.

The fourth bonding insulating layer CINS4 may be disposed below the first peripheral interlayer insulating layer ILD5. The fourth bonding pad 397a may be buried in a lower surface of the fourth bonding insulating layer CINS4.

The first peripheral circuit structure PERI1b and the second peripheral circuit structure PERI2b may be bonded to each other by the third and fourth bonding pads 265, 397a and the third and fourth bonding insulating layers CINS3 and CINS4. The bonding between the third and fourth bonding pads 265 and 397a may be copper (Cu)-copper (Cu) bonding, and the bonding between the third and fourth bonding insulating layers CINS3 and CINS4 may be dielectric-dielectric bonding such as SiCN—SiCN bonding, for example. The first peripheral circuit structure PERI1b and the second peripheral circuit structure PERI2b may be bonded to each other by hybrid bonding including copper (Cu)-copper (Cu) bonding and dielectric-dielectric bonding.

The upper interlayer insulating layer ILD5 may be disposed on an upper surface of the first substrate 301b. The input/output pad 400b may be disposed on an upper surface of the upper interlayer insulating layer ILD5.

The first peripheral circuit structure PERI1b may penetrate or extend into the first substrate 301b and may further include a second through-via 340 electrically connecting the input/output pad 400b to the first peripheral interconnections 373, 375, 383, 385, 393b, and 395b.

The second through-via 340 may penetrate or extend into a portion of the upper interlayer insulating layer ILD5, a portion of the first peripheral interlayer insulating layer ILD4, and the first substrate 301b. The second through-via 340 may be shaped such that a width may decrease toward the first peripheral interlayer insulating layer ILD4.

The semiconductor device 100b may further include a via insulating film 345 at least partially surrounding a side surface of the second through-via 340. The second through-via 340 may include a through-electrode and a barrier layer disposed between the through-via and the via insulating film 345. The barrier layer may enclose a sidewall of the through-electrode and a lower surface of the through-electrode.

The input/output pad 400b may be electrically connected to the cell structure CELLb through the second through-via 340 and the first through-via 240b.

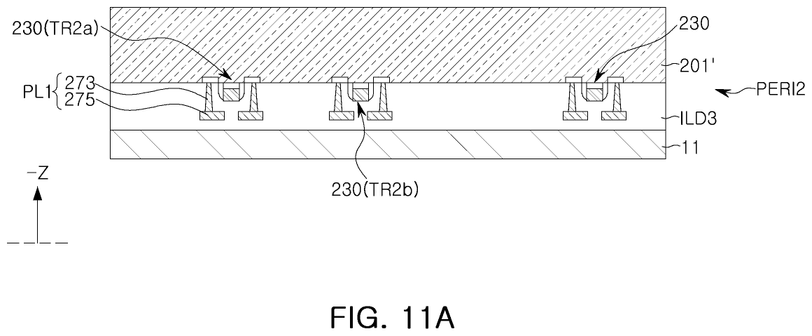

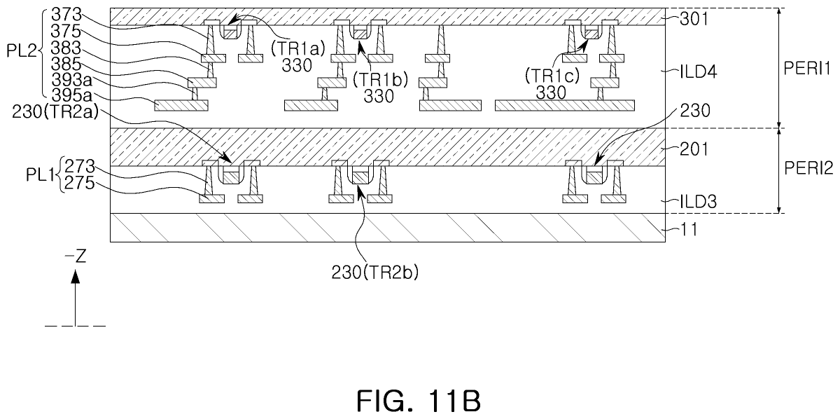

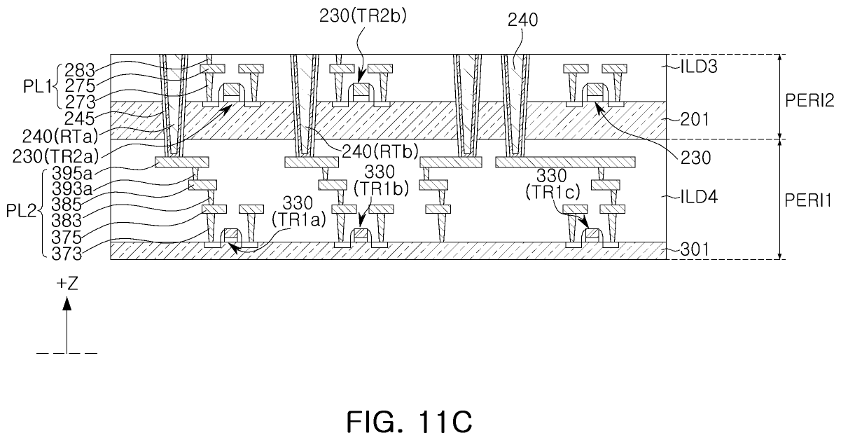

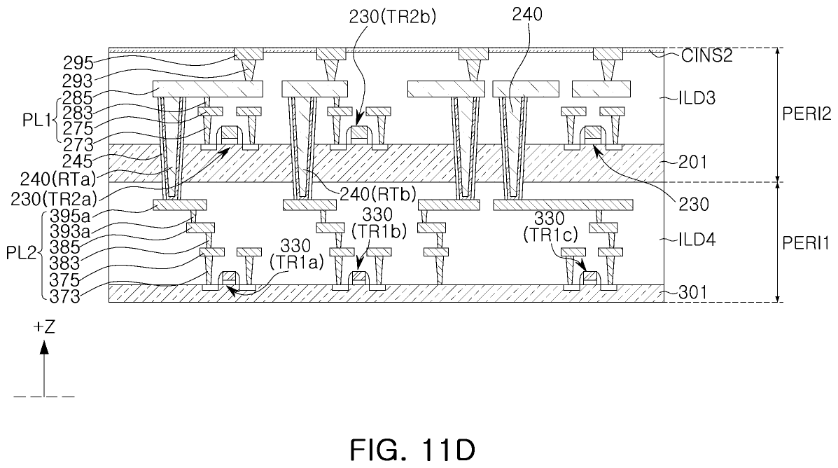

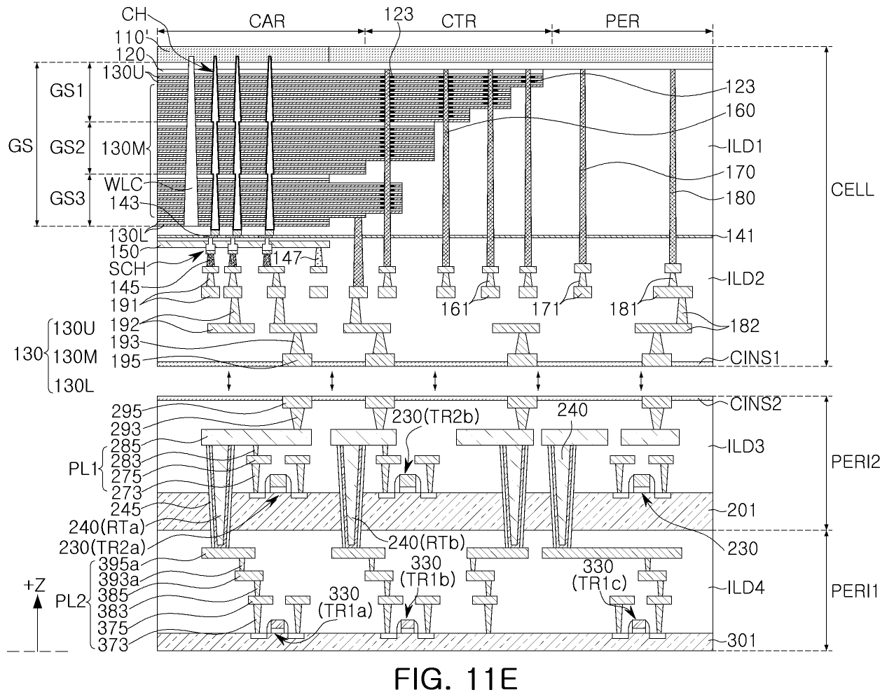

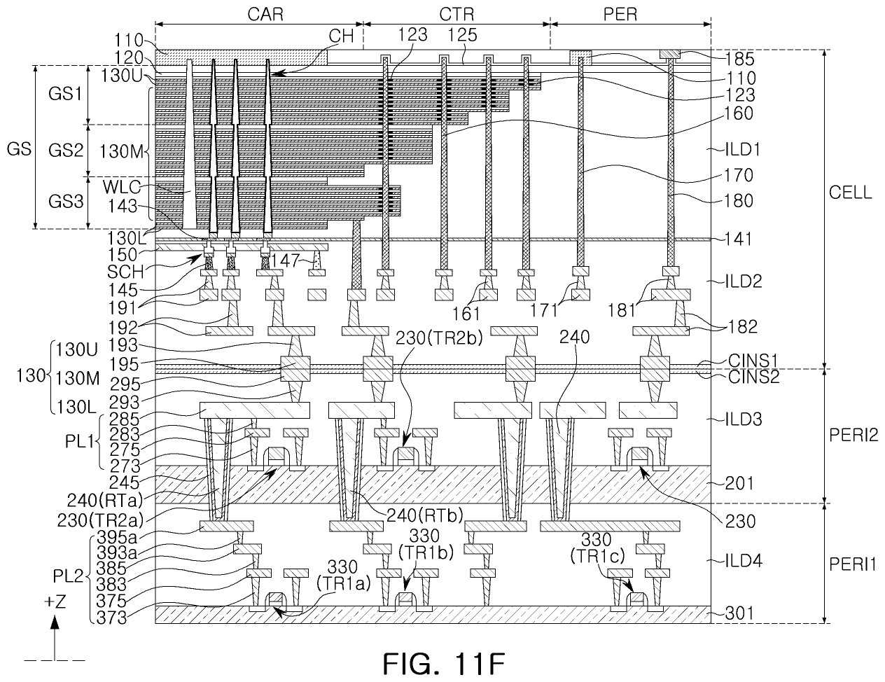

FIGS. 11A to 11F are diagrams illustrating a method of manufacturing the semiconductor device in FIG. 4 according to example embodiments.

Referring to FIGS. 11A to 11F, a method of manufacturing the semiconductor device 100 may include forming a first peripheral circuit structure PERI1 including a first peripheral circuit 330 on a first substrate 301, forming a second peripheral circuit structure PERI1 including a second peripheral circuit 230 on a second substrate 201, forming gate electrodes 130 and channel structures CH and SCH on a plate 110′, forming a cell structure CELL including cell interconnections 161, 171, 181, 182, 191, and 192 electrically connected to the gate electrodes 130 and the channel structures CH and SCH, connecting the first peripheral circuit structure PERI1 to one surface of the formed second peripheral circuit structure PERI2 by a bonding method (see FIG. 11B), and connecting the pre-formed cell structure CELL on the other surface facing the one surface of the second peripheral circuit structure PERI2 by a bonding method (see FIG. 11E).

Referring to FIG. 11A, a second peripheral circuit structure PERI2 including a second peripheral circuit 230 formed on the second preliminary substrate 201′ and a second peripheral interlayer insulating layer ILD3 covering or overlapping the second peripheral circuit 230 in the vertical direction (Z-direction) may be formed on the carrier substrate 11. The second peripheral interlayer insulating layer ILD3 may be in contact with one surface of the carrier substrate 11 such that the second peripheral circuit 230 of the second peripheral circuit structure PERI2 may face the carrier substrate 11.

To form the second peripheral circuit structure PERI2 on the carrier substrate 11, the method may further include forming the second peripheral interconnections PL2 electrically connected to the second peripheral circuit 230 and the second peripheral circuit 230 on second preliminary substrate 201′ and forming the second peripheral interlayer insulating layer ILD3 covering or at least partially overlapping the second peripheral circuit 230 in the vertical direction (Z-direction).

The second peripheral circuit 230 may be configured as a peripheral circuit device having a relatively higher driving voltage. For example, a peripheral circuit TR2a may include a second page buffer (e.g., the second page buffer 21b in FIG. 1B). The peripheral circuit TR2b adjacent to the peripheral circuit TR2a may include a second row decoder (e.g., the second row decoder 22b in FIG. 1B). However, example embodiments thereof are not limited thereto, and the second peripheral circuit 230 may include a common source line driver (e.g., the common source line driver 25 in FIG. 1B and/or a pass circuit (e.g., the pass circuit 26 in FIG. 1B)).

Referring to FIG. 11B, the second substrate 201 may be formed by partially removing the second preliminary substrate 201′, and a first peripheral circuit structure PERI1 including the first peripheral circuit 330 formed on the first substrate 301 and the first peripheral interlayer insulating layer ILD4 covering or at least partially overlapping the first peripheral circuit 330 in the vertical direction (Z-direction) may be formed on the second substrate 201 of the second peripheral circuit structure PERI2. To allow the first peripheral circuit 330 of the first peripheral circuit structure PERI1 to face the second substrate 201, the first peripheral interlayer insulating layer ILD4 may be in contact with one surface of the second substrate 201.

The second preliminary substrate 201′ may be removed or thinned by, for example, lapping, grinding, polishing, or etching processes.

To form the first peripheral circuit structure PERI1 on the second peripheral circuit structure PERI2, the method may further include forming first peripheral interconnections PL1 electrically connected to the first peripheral circuit 330 and the first peripheral circuit 330 on the first substrate 301 and forming the first peripheral interlayer insulating layer ILD4 covering or at least partially overlapping the first peripheral circuit 330 and the first peripheral interconnections PL1 in the vertical direction (Z-direction).

The first peripheral circuit 330 may be configured as a peripheral circuit device having a relatively lower driving voltage. For example, the peripheral circuit TR1a may include a first page buffer (e.g., the first page buffer 21a in FIG. 1B). The peripheral circuit TR1b adjacent to the peripheral circuit TR1a may include a first row decoder (e.g., the first row decoder 22a in FIG. 1B). The peripheral circuit TR1c adjacent to the peripheral circuit TR1b may include a control logic (e.g., the control logic 23 in FIG. 1B) or an input/output circuit (e.g., the input/output circuit 24 in FIG. 1B).

Referring to FIG. 11C, the method may include removing the carrier substrate 11, inverting the first and second peripheral circuit structures PERI1 and PERI2 such that the second peripheral circuit structure PERI2 may be disposed on the first peripheral circuit structure PERI1 (+Z-direction), and forming a first through-via 240 penetrating or extending into the second substrate 201 and electrically connected to the first peripheral interconnections PL1.

Referring to FIG. 11D, the method may include forming a peripheral contact interconnection 285 electrically connecting the first through-via 240 to the second peripheral interconnections 273, 275, and 283, forming second connection structures 293 and 295 on the peripheral contact interconnection 285, and forming a second bonding insulating layer CINS2 on the second peripheral interlayer insulating layer ILD3.

Referring to FIG. 11E, the cell structure CELL may be formed on the second peripheral circuit structure PERI2. The second peripheral circuit structure PERI2 and the cell structure CELL may be connected to each other through the second bonding insulating layer CINS2 of the second peripheral circuit structure PERI2, the first bonding insulating layer CINS1, first connection structures 193 and 195, and the second connection structure 293 and 295.

To form the cell structure CELL on the second peripheral circuit structure PERI2, the method may include forming gate electrodes 130 on the plate 110′, a first channel structure CH penetrating or extending into the gate electrodes 130, a second channel structure SCH connected to the first channel structure CH, and cell interconnections electrically connected to the channel structures CH and SCH. The method may also include forming first and second cell interlayer insulating layers ILD1 and ILD2 covering or at least partially overlapping the gate electrodes 130 in the vertical direction (Z-direction), forming the channel structures CH and SCH and the cell interconnections, and forming the first connection structures 193 and 195 on the cell interconnections (−Z-direction). The cell structure CELL may be formed, and the cell structure CELL may be inverted such that the first bonding insulating layer CINS1 of the cell structure CELL may face the second bonding insulating layer CINS2 of the second peripheral circuit structure PERI2.

Referring to FIG. 11F, the method may include forming a common source plate 110 by partially removing the plate 110′, forming an upper insulating film 125 covering or at least partially overlapping a portion of the cell contact 160 and a portion of the input/output contact 180 in the vertical direction (Z-direction), and forming an input/output connection pad 185 on the input/output contact 180.

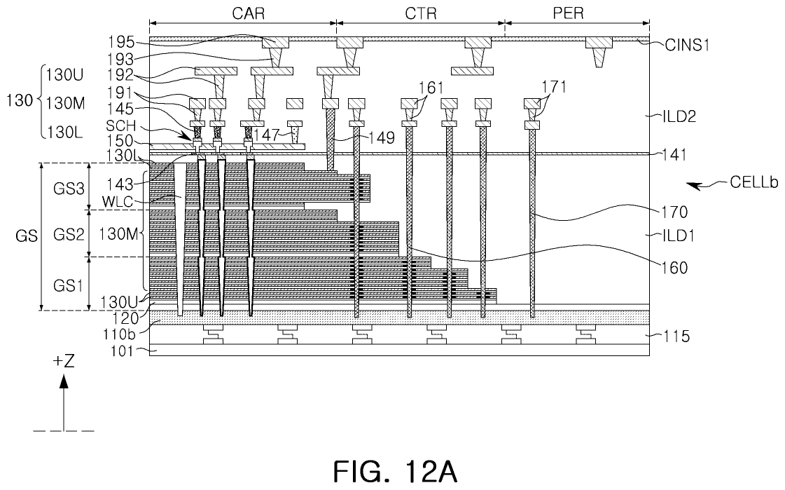

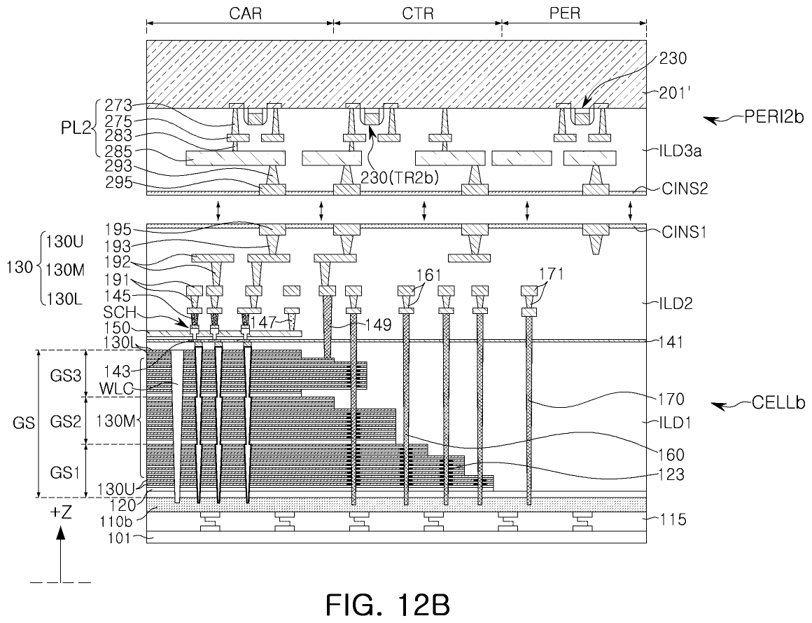

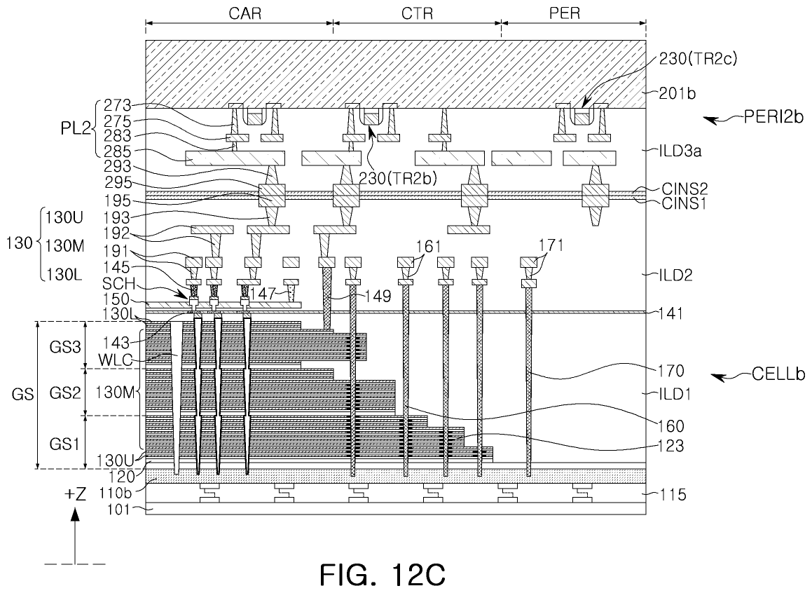

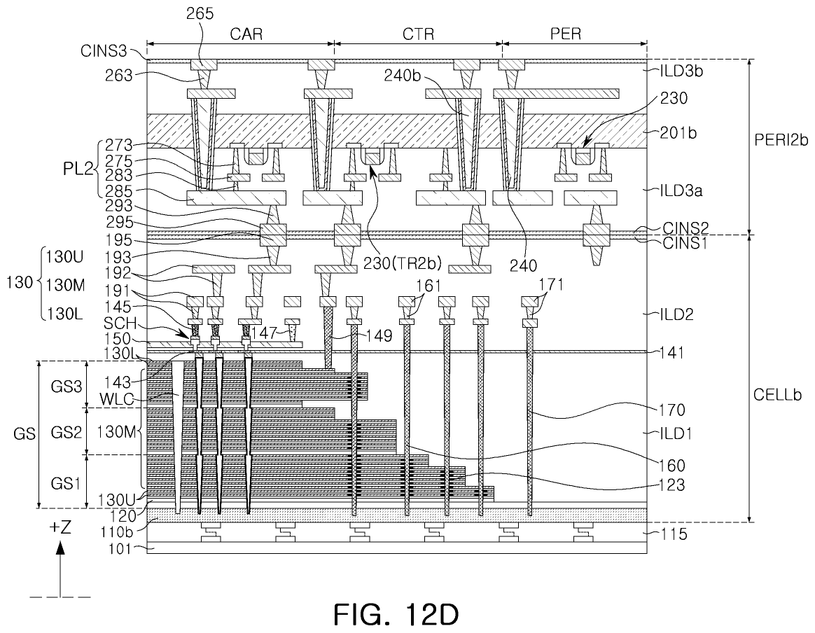

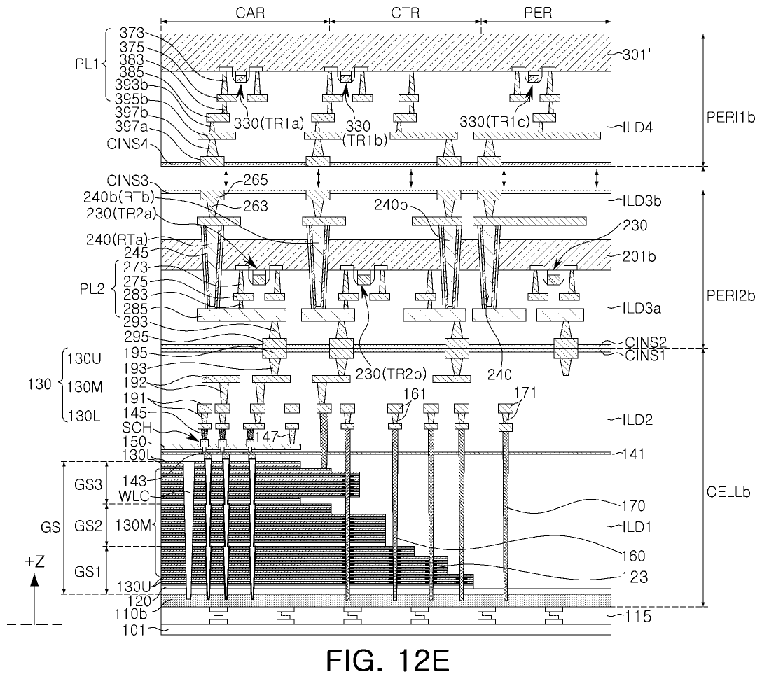

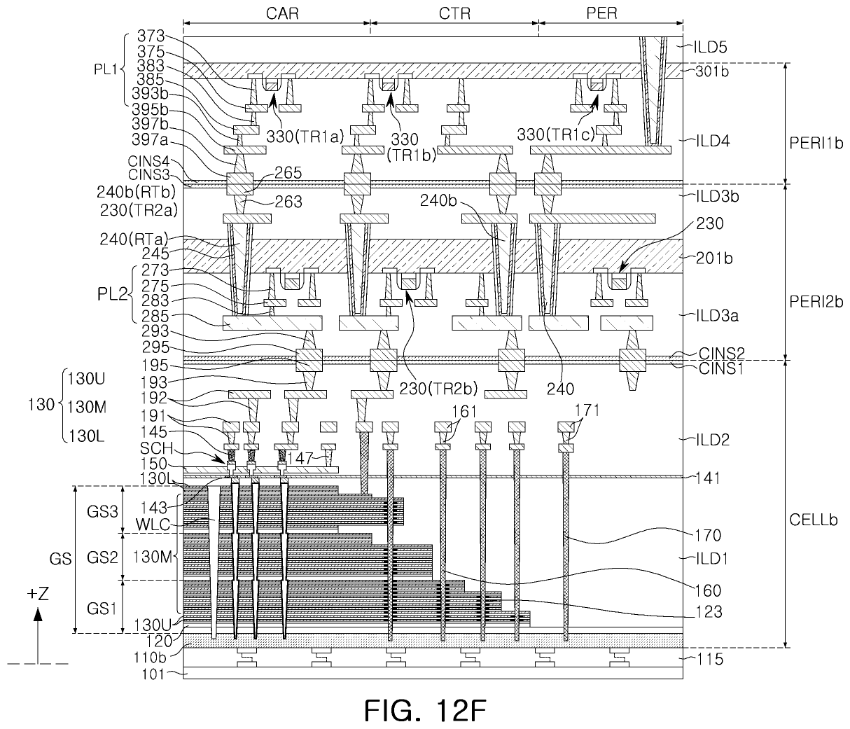

FIGS. 12A to 12F are diagrams illustrating a method of manufacturing the semiconductor device in FIG. 10 according to example embodiments.

Referring to FIGS. 12A to 12F, the method of manufacturing the semiconductor device 100b may include forming a first peripheral circuit structure PERI1b including a first peripheral circuit 330 on the first substrate 301b, forming a second peripheral circuit structure PERI1b including a second peripheral circuit 230 on the second substrate 201b, and forming a cell structure CELLb including a base substrate 101, gate electrodes 130 and channel structures CH and SCH on the base substrate 101. The method may also include forming cell interconnections 161, 171, 191, and 192 electrically connected to the gate electrodes 130 and the channel structures CH and SCH, connecting the second peripheral circuit structure PERI2b to the formed cell structure CELLb by a bonding method (see FIG. 12B), connecting the pre-formed first peripheral circuit structure PERI1b on the second peripheral circuit structure PERI2b by a bonding method (see FIG. 12F), and forming a second through-via 340 penetrating or extending into the first substrate 301b and connected to the first peripheral interconnections PL1 may be included.

Referring to FIG. 12A, the method of manufacturing the semiconductor device includes forming a base substrate 101, an interconnection structure layer 115 on the base substrate 101, and a cell structure CELLb on the interconnection structure layer 115.

The base substrate 101 may be configured as a semiconductor substrate, for example, a semiconductor wafer.

Referring to FIG. 12B, a second peripheral circuit structure PERI2b may be formed on the cell structure CELLb.

The second peripheral circuit structure PERI2b and the cell structure CELLb may be connected to each other through the first and second bonding insulating layers CINS1 and CINS2, the first connection structure 193 and 195, and the second connection structure 293 and 295.

To form the second peripheral circuit structure PERI2b on the cell structure CELLb, the method may further include forming second peripheral interconnections PL2 electrically connected to the second peripheral circuit 230 and the second peripheral circuit 230 on the second preliminary substrate 201′, and forming a peripheral interlayer insulating layer ILD3a covering or at least partially overlapping the second peripheral circuit 230 in the vertical direction (Z-direction).

Referring to FIG. 12C, the second substrate 201b may be formed by partially removing the second preliminary substrate 201′.

Referring to FIG. 12D, the method of manufacturing the semiconductor device includes forming a peripheral interlayer insulating layer ILD3b on the second substrate 201b, forming a first through-via 240d penetrating or extending into the second substrate 301b and electrically connected to the second peripheral interconnections PL2, forming third connection structures 263 and 265 on the first through-via 240d, and forming a third bonding insulating layer CINS3 on the interlayer insulating layer ILD3b.

A peripheral interlayer insulating layer ILD3a may be formed below the second substrate 201b (−Z-direction), and a peripheral interlayer insulating layer ILD3b may be formed on the second substrate 201b (+Z-direction). The first through-via 240d may penetrate or extend into the second substrate 201b and may electrically connect the second peripheral interconnections PL2 disposed on the lower surface of the second substrate 201b to the third connection structures 263 and 265 disposed on the second substrate 201b.

Referring to FIG. 12E, the first peripheral interconnection structure PERI1b may be formed on the second peripheral interconnection structure PERI2b.

To form the first peripheral interconnection structure PERI1b on the second peripheral interconnection structure PERI2b, the method may include forming first peripheral interconnections PL1 electrically connected to the first peripheral circuit 330 and the first peripheral circuit 330 on the first preliminary substrate 301′, forming a first peripheral interlayer insulating layer ILD4 covering or at least partially overlapping the first peripheral circuit 330 and the first peripheral interconnections PL1 in the vertical direction (Z-direction), forming fourth connection structures 397a and 397b on the first peripheral interlayer insulating layer ILD4 (−Z-direction), and forming the fourth bonding insulating layer CINS4 on the first peripheral interlayer insulating layer ILD4.

The first and third peripheral circuit structures PERI1b and PERI2b may be connected to each other through the third and fourth bonding insulating layers CINS3 and CINS4, the third connection structure 263 and 265, and the fourth connection structure 397a and 397b.

Referring to FIG. 12F, the method of manufacturing the semiconductor device includes forming a first substrate 301b by partially removing the first preliminary substrate 301′, forming an upper interlayer insulating layer ILD5 on the first substrate 301b, and forming a second through-via 340 penetrating or extending into the upper interlayer insulating layer ILD5 and the first substrate 301 and connected to the first peripheral interconnections PL1.

Thereafter, referring to FIG. 10, an input/output pad 400b may be formed on the second through-via 340. The input/output pad 400b may be electrically connected to the first peripheral interconnections PL1 through the second through-via 340. Accordingly, the semiconductor device 100b may be manufactured.

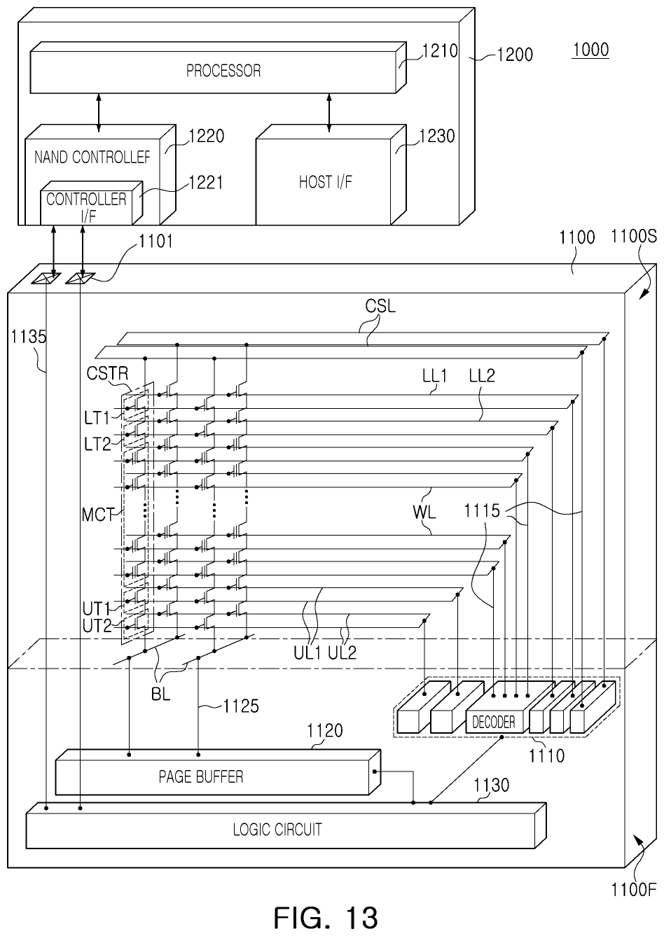

FIG. 13 is a diagram illustrating a data storage system including a semiconductor device according to example embodiments.

Referring to FIG. 13, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1A to 3B. The semiconductor device 1100 may include a first structure 1100F and a second structure 1100S on the first structure 1100F. In the example embodiments, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bit line BL, a common source line CSL, word lines WL, first and second gate upper lines UL1 and UL2, first and second gate lower lines LL1 and LL2 and memory cell strings CSTR disposed between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example embodiments. In the example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The word lines WL may be configured as gate electrodes of the memory cell transistors MCT, and the gate upper lines UL1 and UL2 may be configured as gate electrodes of the upper transistors UT1 and UT2, respectively.

In the example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In the example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

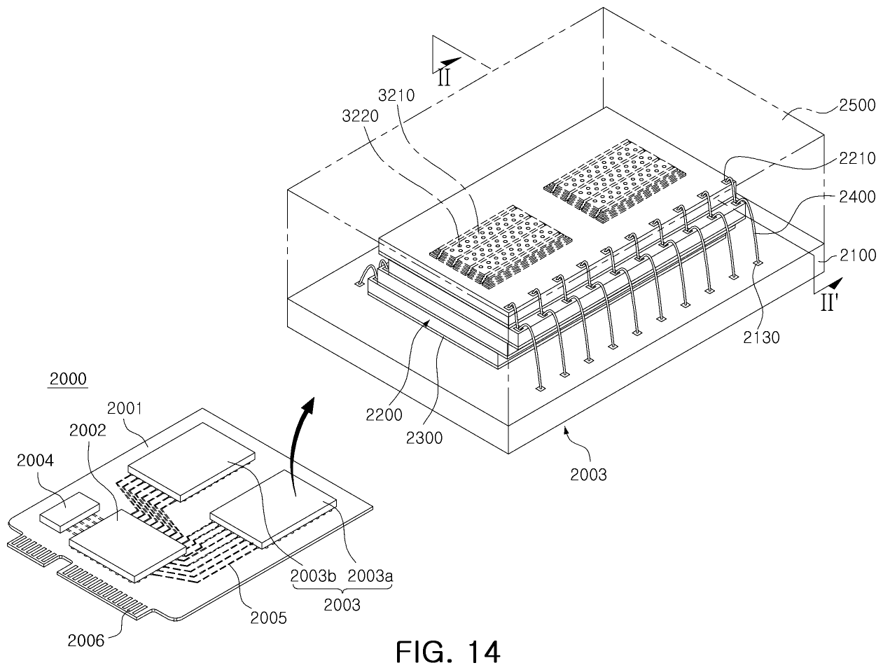

FIG. 14 is a perspective diagram illustrating a data storage system including a semiconductor device according to example embodiments.

Referring to FIG. 14, a data storage system 2000 in example embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003 and 2003b spaced apart from each other. Each of the first and second semiconductor packages 2003 and 2003b may be configured as a semiconductor package including a plurality of semiconductor chips 2200. Each of the first and second semiconductor packages 2003 and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering or at least partially overlapping the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 13. Each of the semiconductor chips 2200 may include gate stack structures 4210 and channel structures 4220. Each of the semiconductor chips 2200 may include the semiconductor device described in the aforementioned example embodiment with reference to FIGS. 1A to 3B.

In the example embodiments, the connection structure 2400 may be configured as a bonding wire electrically connecting the input/output pad 2210 to the upper package pads 2130. Accordingly, in each of the first and second semiconductor packages 2003 and 2003b, the semiconductor chips 2200 may be electrically connected to each other by a bonding wire method, and may be electrically connected to the package upper pads 2130 of the package substrate 2100. In the example embodiments, in each of the first and second semiconductor packages 2003 and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In example embodiments, the controller 2002 and the semiconductor chips 2200 may be mounted on an interposer substrate different from the main board 2001, and the controller 2002 and the semiconductor chips 2200 may be connected to each other by interconnection formed on the interposer substrate.

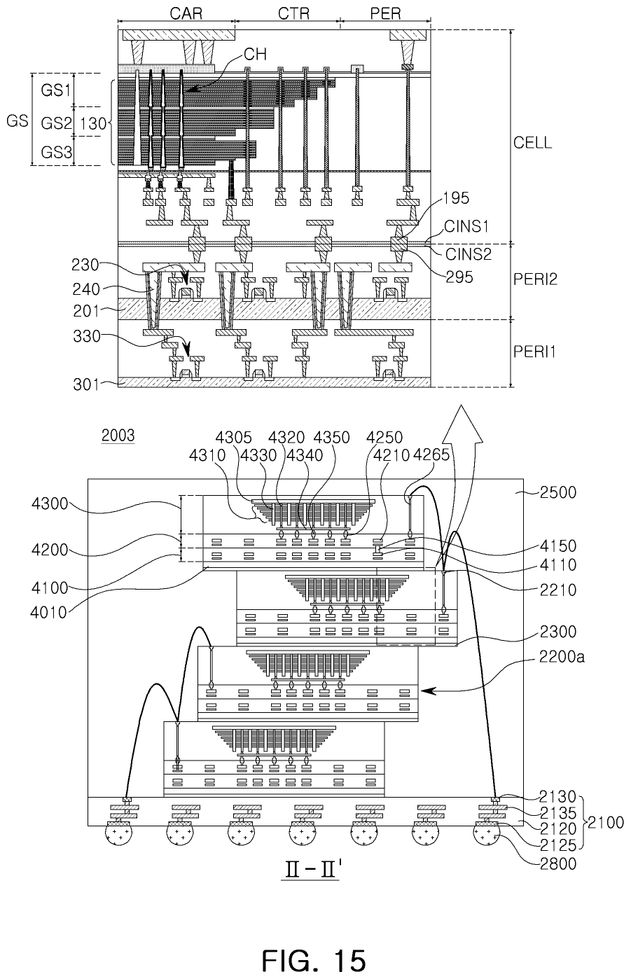

FIG. 15 is a cross-sectional diagram illustrating a semiconductor package according to example embodiments, illustrating example embodiments of the semiconductor package 2003 in FIG. 14 taken along line II-II′.

Referring to FIG. 15, in the semiconductor package 2003, the package substrate 2100 may be implemented as a printed circuit substrate. The package substrate 2100 may include a package substrate body portion 2120, package upper pads 2130 disposed on an upper surface of the package substrate body portion 2120, lower pads 2125 disposed on the lower surface of the package substrate body 2120 or exposed through the lower surface, and internal interconnections 2135 electrically connecting the upper pads 2130 to the lower pads 2125 in the package substrate body 2120. The lower pads 2125 may be connected to the interconnection patterns 2005 of the main board 2001 of the data storage system 2000 through the conductive connection portions 2800 as illustrated in FIG. 14.

In the semiconductor package 2003, each of the semiconductor chips 2200a may include a semiconductor substrate 4010, a first semiconductor structure 4100 (or a first peripheral circuit structure PERI1) on the semiconductor substrate 4010, a second semiconductor structure 4200 (or a second peripheral circuit structure PERI2) bonded to the first semiconductor structure 4100 on the first semiconductor structure 4100, and a third semiconductor structure 4300 (or a cell structure CELL) bonded to the second semiconductor structure 4200 on the second semiconductor structure 4200. The first semiconductor structure 4100 may include a first peripheral circuit region including a first peripheral interconnection 4110 and a connection structure 4150. The second semiconductor structure 4200 may include a second peripheral circuit region including a second peripheral interconnection 4210 and a lower bonding structure 4250. The third semiconductor structure 4300 may include a common source line 4305, a gate stack structure 4310 between the common source line 4305 and the second semiconductor structure 4200, channel structures 4320 and isolation structure 4330 penetrating or extending into the gate stack structure 4310, and an upper bonding structure 4350 electrically connected to word lines of the channel structures 4320 and the gate stack structures 4310. For example, the upper bonding structure 4350 may be electrically connected to the channel structures 4320 and the word lines through bit lines 4340 electrically connected to the channel structures 4320 and cell contacts electrically connected to the word lines (e.g., the cell contacts 160 in FIG. 4).

The first peripheral interlayer insulating layer (e.g., the first peripheral interlayer insulating layer ILD4 in FIG. 4) of the first semiconductor structure 4100 and the second substrate (e.g., the second substrate 201 in FIG. 4) of the second semiconductor structure 4200 may be in contact with and bonded to each other.

The lower bonding structure 4250 of the second semiconductor structure 4200 and the upper bonding structure 4350 of the third semiconductor structure 4300 may be in contact with and bonded to each other. The bonding portions of the lower bonding structure 4250 and the upper bonding structure 4350 may be formed of copper (Cu), for example.

As illustrated in the enlarged diagram illustrating the first semiconductor structure 4100, the second semiconductor structure 4200, and the third semiconductor structure 4300, the first semiconductor structure 4100 may further include a first substrate 301 and a first peripheral circuit 330 on the first substrate 301. The second semiconductor structure 4200 may further include a second substrate 201 and a second peripheral circuit 230 on the second substrate 201.

The first peripheral interconnection 4110 of the first semiconductor structure 4100 and the second peripheral interconnection 4210 of the second semiconductor structure 4200 may be electrically connected to each other by the connection structure 4150. The third semiconductor structure 4300 may include a gate structure GS corresponding to the gate stack structure 4310 and first channel structures CH corresponding to the channel structures 4320.

The lower bonding structure 4250 of the second semiconductor structure 4200 may be buried in the second bonding insulating layer CINS2 disposed on an upper surface of the second semiconductor structure 4200. The upper bonding structure 4350 of the third semiconductor structure 4300 may be buried in the first bonding insulating layer CINS1 disposed in an upper portion of the third semiconductor structure 4300.

Each of the semiconductor chips 2200a may further include an input/output pad 2210 and an input/output connection interconnection 4265 below the input/output pad 2210. The input/output connection interconnection 4265 may be electrically connected to a portion of the second peripheral interconnection 4210. The input/output pad 2210 may be configured as a region including an input/output pad (e.g., the input/output pad 400a in FIG. 4).

The semiconductor chips 2200 in FIG. 15 may be electrically connected to each other by the connection structures 2400 in the form of bonding wires. However, in the other example embodiment, semiconductor chips in a semiconductor package, such as the semiconductor chips 2200 in FIG. 15, may be electrically connected to each other by a connection structure including a through electrode (TSV).

According to the aforementioned example embodiments, by including a first chip structure, a second chip structure and a cell structure disposed in order, disposing the first peripheral circuit having a low driving voltage on the first chip structure, and disposing the second peripheral circuit having a high driving voltage in the second chip structure in the semiconductor device, integration density of the semiconductor device may be improved, and an electrical path between peripheral circuits may be configured efficiently, thereby improving performance of the semiconductor device.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first peripheral circuit structure comprising:
a first substrate that comprises a first page buffer region,
a first peripheral circuit that is on the first page buffer region and comprises a first gate stack that extends from the first substrate by a first height in a first direction that is perpendicular to a first surface of the first substrate, and
first peripheral interconnections electrically connected to the first peripheral circuit;
a second peripheral circuit structure on the first peripheral circuit structure, wherein the second peripheral circuit structure comprises:
a second substrate comprising a second page buffer region that at least partially overlaps the first page buffer region in the first direction,
a second peripheral circuit that is on the second page buffer region and comprises a second gate stack that extends from the second substrate by a second height in the first direction, wherein the second height is greater than the first height, and
second peripheral interconnections electrically connected to the second peripheral circuit;
a first through-via that extends into the second substrate and electrically connects the first peripheral interconnections to the second peripheral interconnections; and
a cell structure on the second peripheral circuit structure, wherein the cell structure comprises:
gate electrodes,
channel structures that extend into the gate electrodes, and
cell interconnections electrically connected to the gate electrodes and the channel structures.

2. The semiconductor device of claim 1,
wherein the first gate stack of the first peripheral circuit comprises a first gate insulating film having a first dielectric constant, and
wherein the second gate stack of the second peripheral circuit comprises a second gate insulating film having a second dielectric constant that is less than the first dielectric constant.

3. The semiconductor device of claim 1, wherein a first channel width of the first peripheral circuit in a second direction that is perpendicular to the first direction is less than a second channel width of the second peripheral circuit in the second direction

4. The semiconductor device of claim 1, wherein a first thickness of the first substrate in the first direction is less than a second thickness of the second substrate in the first direction.

5. The semiconductor device of claim 1,
wherein the second peripheral circuit structure further comprises a second bonding insulating layer that is on the second peripheral interconnections and the second peripheral circuit, and
wherein the cell structure further comprises a first bonding insulating layer between the cell interconnections and the second bonding insulating layer.

6. The semiconductor device of claim 1,
wherein the first peripheral circuit structure further comprises a third peripheral circuit comprising a third gate stack that extends from the first substrate by a third height in the first direction, and
wherein the second peripheral circuit structure further comprises a fourth peripheral circuit comprising a fourth gate stack that extends from the second substrate by the third height in the first direction.

7. The semiconductor device of claim 6,
wherein the first substrate further comprises a first row decoder region spaced apart from the first page buffer region in a second direction that is perpendicular to the first direction,
wherein the second substrate further comprises a second row decoder region that at least partially overlaps the first row decoder region in the first direction,
wherein the third peripheral circuit is on the first row decoder region, and
wherein the fourth peripheral circuit is on the second row decoder region.

8. The semiconductor device of claim 6, wherein the third height is less than the first height and greater than the second height.

9. The semiconductor device of claim 6,
wherein the third gate stack of the third peripheral circuit comprises a third gate insulating film having a third dielectric constant, and
wherein the fourth gate stack of the fourth peripheral circuit comprises a fourth gate insulating film having a fourth dielectric constant that is less than the third dielectric constant.

10. The semiconductor device of claim 1,
wherein the first substrate comprises a second surface opposing the first surface, and
wherein the first peripheral circuit structure further comprises:
an input/output pad on the second surface; and
a second through-via that extends into the first substrate and electrically connects the first peripheral interconnections to the input/output pad.

11. The semiconductor device of claim 9,
wherein the second substrate comprises a third surface and a fourth surface opposing the third surface,
wherein the second peripheral circuit is on the third surface,
wherein the second peripheral circuit structure further comprises a third bonding insulating layer on the third surface, and
wherein the first peripheral circuit structure further comprises a fourth bonding insulating layer on the first peripheral interconnections, the first peripheral circuit, and the third bonding insulating layer.

12. The semiconductor device of claim 1, wherein the channel structures at least partially overlap the first page buffer region in the first direction.

13. The semiconductor device of claim 1,
wherein the cell structure further comprises:
cell contacts spaced apart from the channel structures in a second direction that is perpendicular to the first direction;
input/output contacts spaced apart from the channel structures and the cell contacts in a third direction intersecting the second direction; and
an input/output pad that is on the input/output contact and electrically connected to the input/output contact, and
wherein the second peripheral circuit structure further includes a pass circuit that at least partially overlaps the cell contacts in the first direction and is electrically connected to the cell contacts.

14. A semiconductor device, comprising:
a first peripheral circuit structure comprising:
a first substrate,
a first peripheral circuit that comprises a first gate stack that is on the first substrate and extends from the first substrate by a first height in a first direction that is perpendicular to a first surface of the first substrate,
first peripheral interconnections electrically connected to the first peripheral circuit, and
a first interlayer insulating layer that at least partially overlaps the first peripheral circuit and the first peripheral interconnections in the first direction;
a second peripheral circuit structure comprising:
a second substrate that contacts the first interlayer insulating layer,
a second peripheral circuit that comprises a second gate stack that is on the second substrate and extends from the second substrate by a second height in the first direction that is greater than the first height,
second peripheral interconnections electrically connected to the second peripheral circuit, and
a first bonding pad electrically connected to the second peripheral interconnections; and
a cell structure comprising:
a second bonding pad on the first bonding pad,
gate electrodes,
channel structures that extend in the first direction and extend into the gate electrodes, and
cell interconnections electrically connected to the gate electrodes and the channel structures.

15. The semiconductor device of claim 14,
wherein the first peripheral circuit has a first operating voltage, and
wherein the second peripheral circuit has a second operating voltage that is greater than the first operating voltage.

16. The semiconductor device of claim 14,
wherein the first gate stack comprises a first gate insulating film, a first metal pattern on the first gate insulating film, and a first polysilicon on the first metal pattern,
wherein the second gate stack comprises a second gate insulating film and a second polysilicon on the second gate insulating film, and
wherein the first gate insulating film has a first dielectric constant, and
wherein the second gate insulating film has a second dielectric constant that is less than the first dielectric constant.

17. The semiconductor device of claim 16,
wherein the first peripheral circuit further comprises a metal-semiconductor channel layer, and
wherein the first gate stack is on the metal-semiconductor channel layer.

18. A semiconductor device, comprising:
a substrate comprising a cell array region, a cell contact region, and a peripheral region;
a first peripheral circuit structure on the substrate, wherein the first peripheral circuit structure comprises:
a first page buffer that at least partially overlaps the cell array region in a first direction that is perpendicular to an upper surface of the substrate and has a first operating voltage, and
a first row decoder that at least partially overlaps the cell contact region in the first direction and has a second operating voltage;
a second peripheral circuit structure on the first peripheral circuit structure, wherein the second peripheral circuit structure comprises:
a second page buffer that at least partially overlaps the cell array region in the first direction and has a third operating voltage that is greater than the first operating voltage, and
a second row decoder that at least partially overlaps the cell contact region in the first direction and has a fourth operating voltage that is greater than the second operating voltage; and
a cell structure on the second peripheral circuit structure, wherein the cell structure comprises:
gate electrodes,
channel structures that extend into the gate electrodes and are on the cell array region, and
cell contacts that at least partially overlap the cell contact region in the first direction,
wherein the second peripheral circuit structure comprises a pass circuit that is between the second page buffer and the second row decoder and is configured to provide a fifth operating voltage that is greater than the first operating voltage and the second operating voltage to the cell contacts.

19. The semiconductor device of claim 18,
wherein the cell structure further comprises an input/output contact that is spaced apart from the channel structures and the cell contacts in a second direction that intersects the first direction and is on the peripheral region, and
wherein the second peripheral circuit structure further includes an input/output circuit electrically connected to the input/output contact.

20. The semiconductor device of claim 18,
wherein the first peripheral circuit structure further comprises a control logic circuit, and
wherein the control logic circuit does not overlap the second page buffer and the second row decoder in the first direction.
